(19) United States
(12) Patent Application Publication
(10) Pub. No.: US 2025/0232965 A1
(43) Pub. Date: Jul. 17, 2025

(54) SUBSTRATE PROCESSING SYSTEM

(71) Applicant: Tokyo Electron Limited, Tokyo (JP)

(72) Inventors: Tatsuru OKAMURA, Miyagi (JP); Toshiyuki MAKABE, Miyagi (JP); Masatomo KITA, Miyagi (JP); Yoshihiro YANAGI, Miyagi (JP)

(73) Assignee: Tokyo Electron Limited, Tokyo (JP)

(21) Appl. No.: 19/170,201

(22) Filed: Apr. 4, 2025

Related U.S. Application Data
(63) Continuation of application No. PCT/JP2023/034920, filed on Sep. 26, 2023.

(30) Foreign Application Priority Data
Oct. 7, 2022 (JP) 2022-162608

(51) Int. Cl. H01J 37/32

(52) U.S. Cl. CPC H01J 37/32807; H01J 37/32642; H01J 37/32715; H01J 37/3288; H01J 37/32889

(57) ABSTRACT

A substrate processing system includes: a processing module including a processing chamber and a substrate support provided inside the processing chamber, the substrate support having a substrate support surface and a ring support surface for supporting a ring; a vacuum transfer module connected to the processing module and including a transfer robot for transferring the ring; a ring storage module connected to the vacuum transfer module to store the ring; a temperature adjuster provided in the ring storage module to adjust a temperature of the ring; a controller that sequentially execute: adjusting the temperature of the ring by the temperature adjuster before loading the ring into the processing module; and transferring, by the transfer robot, the ring, the temperature of which has been adjusted by the temperature adjuster, so as to place the ring on the substrate support.

### CROSS-REFERENCE TO RELATED APPLICATIONS

This application is a bypass continuation application of International Application No. PCT/JP2023/034920 having an international filing date of Sep. 26, 2023 and designating the United States, the international application being based upon and claiming the benefit of priority from Japanese Patent Application No. 2022-162608, filed on Oct. 7, 2022, the entire contents of each are incorporated herein by reference.

### TECHNICAL FIELD

The present disclosure relates to a substrate processing system.

### BACKGROUND

Patent Document 1 discloses a substrate processing system that performs substrate processing (plasma processing) by arranging a focus ring around a stage (substrate support) on which a substrate is placed. When the focus ring needs to be replaced, the substrate processing system unloads the focus ring from an interior of a processing chamber using a transfer device, cleans a surface of the stage on which the focus ring is placed, and then loads the focus ring into the processing chamber using the transfer device.

### PRIOR ART DOCUMENT

### Patent Document

Patent Document 1: Japanese Laid-Open Patent Publication No. 2018-010992

### SUMMARY

According to one embodiment of the present disclosure, a substrate processing system includes: a processing module including a processing chamber and a substrate support provided inside the processing chamber, the substrate support having a substrate support surface and a ring support surface that surrounds the substrate support surface to support at least one ring; a vacuum transfer module connected to the processing module and including a transfer robot configured to transfer the at least one ring; a ring storage module connected to the vacuum transfer module and configured to be capable of storing the at least one ring; a temperature adjuster provided in the ring storage module and configured to be capable of adjusting a temperature of the at least one ring; a controller configured to sequentially execute: adjusting the temperature of the at least one ring by the temperature adjuster before loading the at least one ring into the processing module; and transferring, by the transfer robot, the at least one ring, the temperature of which has been adjusted by the temperature adjuster, so as to place the at least one ring on the substrate support.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a diagram illustrating an example of a substrate processing system according to an embodiment.

FIG. 2 is a schematic cross-sectional view illustrating an example of a plasma processing apparatus.

FIG. 3 is a partial enlarged view of FIG. 2.

FIG. 4 is a first schematic side cross-sectional view illustrating a ring storage module.

FIG. 5 is a second schematic side cross-sectional view of the ring storage module as viewed in a direction orthogonal to that in FIG. 4.

FIG. 6 is a flowchart illustrating a transfer method of a first example.

FIG. 7 is a flowchart illustrating an example of a procedure of Operation.

FIG. 8 is a flowchart illustrating a transfer method of a second example.

FIG. 9 is a flowchart illustrating a transfer method of a third example.

FIG. 10 is a partial enlarged view of a plasma processing apparatus according to another embodiment.

FIG. 11 is a drawing illustrating an example of a substrate processing system according to another embodiment.

FIG. 12 is a flowchart illustrating a transfer method of a fourth example.

FIG. 13 is a flowchart illustrating a transfer method of a fifth example.

### DETAILED DESCRIPTION

Hereinafter, embodiments for carrying out the present disclosure will be described with reference to the drawings. In each drawing, the same components will be indicated by the same reference numerals, and redundant descriptions thereof will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### [Substrate Processing System]

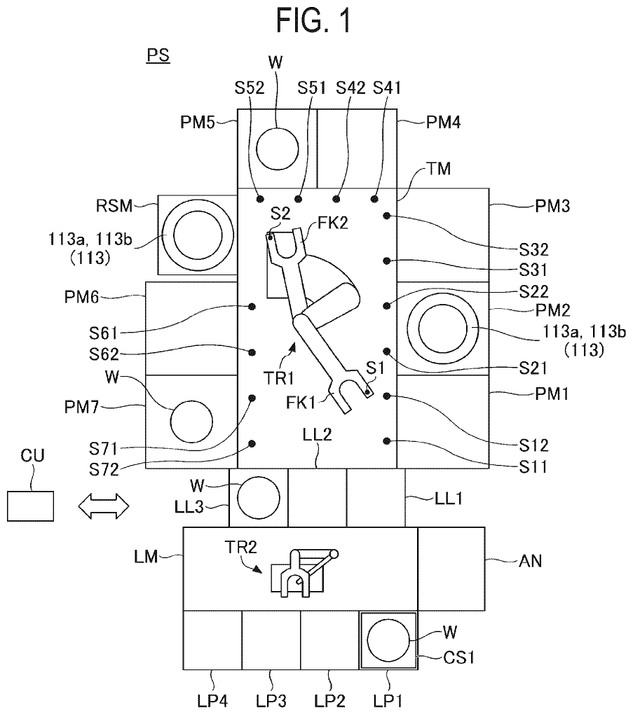

Referring to FIG. 1, a substrate processing system PS according to an embodiment will be described. FIG. 1 is a diagram illustrating an example of the substrate processing system PS according to an embodiment. As illustrated in FIG. 1, the substrate processing system PS is a system capable of performing various types of processing, such as plasma processing, on a substrate W. The substrate W may be, for example, a semiconductor wafer.

The substrate processing system PS includes a vacuum transfer module TM, a plurality of processing modules PM1 to PM7, a ring storage module RSM, a plurality of load lock modules LL1 to LL3, an atmospheric transfer module LM, load ports LP1 to LP4, an aligner AN, and a controller CU. The vacuum transfer module TM is also referred to as a “transfer module.” The processing modules PM1 to PM7 are also referred to as “process modules”. The ring storage module RSM is also referred to as a “ring stocker module”. The atmospheric transfer module LM is also referred to as a “loader module”.

The vacuum transfer module TM has a rectangular shape in a plan view. The vacuum transfer module TM is connected to the processing modules PM1 to PM7, the load lock modules LL1 to LL3, and the ring storage module RSM. The vacuum transfer module TM includes a vacuum transfer chamber. An interior of the vacuum transfer chamber is maintained in a vacuum atmosphere. A transfer robot TR1 is provided in the vacuum transfer chamber (in an interior of the vacuum transfer module TM).

The transfer robot TR1 is configured to be swingable, extendible, and movable up and down. The transfer robot TR1 includes an upper fork FK1 and a lower fork FK2. The upper fork FK1 and the lower fork FK2 of the transfer robot TR1 are configured to be capable of holding the substrate W and a ring 113 (including an inner ring 113a and an outer ring 113b), respectively. The transfer robot TR1 holds and transfers the substrate W and the ring 113 between the processing modules PM1 to PM7, the load lock modules LL1 to LL3, and the ring storage module RSM.

The upper fork FK1 is provided with a position detection sensor S1. The lower fork FK2 is provided with a position detection sensor S2. The position detection sensors S1 and S2 detect positions of the inner ring 113a and the outer ring 113b placed in the processing modules PM1 to PM7. The position detection sensors S1 and S2 may be, for example, optical displacement sensors, cameras, or other similar devices.

The vacuum transfer module TM may be provided with position detection sensors S11 and S12. The position detection sensors S11 and S12 are provided on a transfer path of the substrate W and the ring 113 (the inner ring 113a) from the vacuum transfer module TM to the processing module PM1. The position detection sensors S11 and S12 are used when loading the substrate W or the ring 113 from the vacuum transfer module TM into the processing module PM1, as well as when unloading the substrate W or the ring 113 from the processing module PM1 into the vacuum transfer module TM. The position detection sensors S11 and S12 are provided, for example, near a gate valve (not illustrated) that partitions the vacuum transfer module TM from the processing module PM1. The position detection sensors S11 and S12 are arranged such that a distance therebetween is, for example, smaller than an outer diameter of the substrate W and also smaller than an inner diameter of the inner ring 113a. The vacuum transfer module TM may also be provided with additional position detection sensors S21, S22, S31, S32, S41, S42, S51, S52, S61, S62, S71 and S72, similar to the position detection sensors S11 and S12.

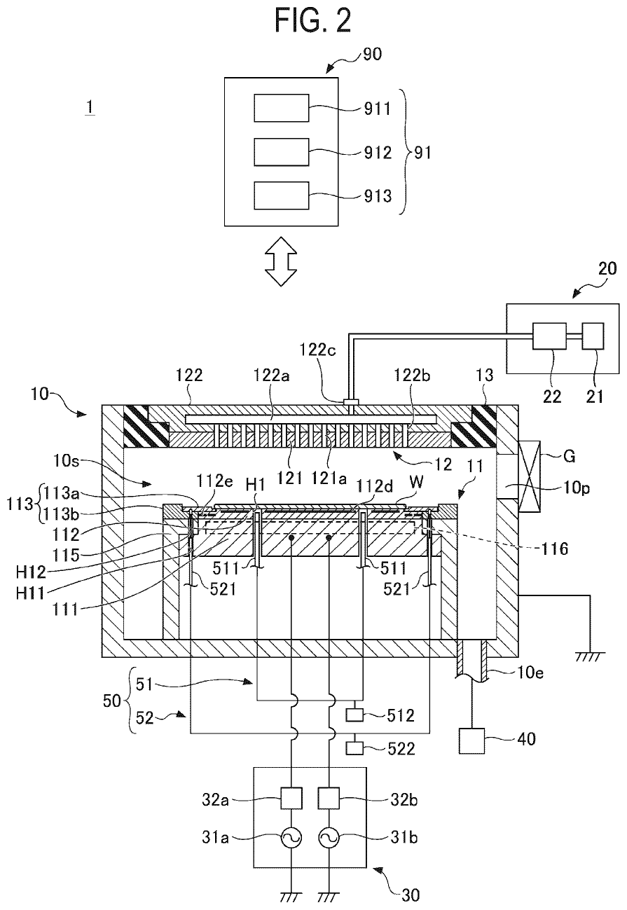

The processing modules PM1 to PM7 are connected to the vacuum transfer module TM. Each of the processing modules PM1 to PM7 includes a vacuum processing chamber. A substrate support 11 (see FIG. 2) is provided in the interior of the vacuum processing chamber. After the substrate W is placed on the substrate support 11, interiors of the processing modules PM1 to PM7 are depressurized so that a processing gas is introduced into the interiors, RF power is applied to generate plasma, and plasma processing is performed on the substrate W with the plasma. The vacuum transfer module TM and the processing modules PM1 to PM7 are partitioned from each other by openable/closable gate valves (not illustrated).

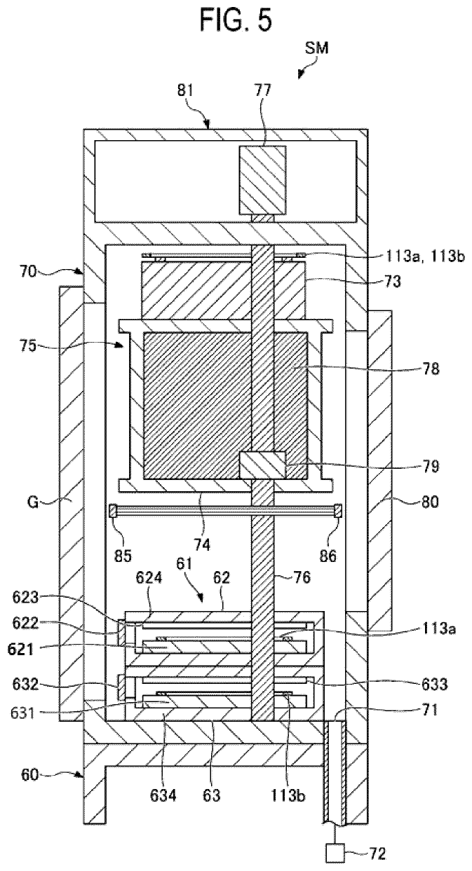

The ring storage module RSM is an example of a device for storing the ring 113 and is connected to the vacuum transfer module TM. The ring storage module RSM stores, for example, the inner ring 113a and the outer ring 113b, which constitute the ring 113. The ring storage module RSM may be configured to store the inner ring 113a alone. The ring storage module RSM may be configured to store the outer ring 113b alone. The inner ring 113a and the outer ring 113b are transferred between the processing modules PM1 to PM7 and the ring storage module RSM by the transfer robot TR1. The vacuum transfer module TM and the ring storage module RSM are partitioned from each other by an openable/closable gate valve G (see FIG. 5).

The load lock modules LL1 to LL3 are provided between the vacuum transfer module TM and the atmospheric transfer module LM. The load lock modules LL1 to LL3 are connected to the vacuum transfer module TM and the atmospheric transfer module LM. Each of the load lock modules LL1 to LL3 includes an internal pressure-variable chamber, which is switchable between a vacuum and atmospheric pressure. A stage (not illustrated) on which the substrate W may be placed is provided in the internal pressure-variable chamber. When transferring the substrate W from the atmospheric transfer module LM to the vacuum transfer module TM, each of the load lock modules LL1 to LL3 maintains the internal pressure-variable chamber thereof in the atmospheric pressure to receive the substrate W from the atmospheric transfer module LM, and then reduces an internal pressure of the internal pressure-variable chamber to deliver the substrate W to the vacuum transfer module TM. When transferring the substrate W from the vacuum transfer module LM to the atmospheric transfer module TM, each of the load lock modules LL1 to LL3 maintains the internal pressure-variable chamber in the vacuum to receive the substrate W from the vacuum transfer module TM, and then increases the internal pressure of the internal pressure-variable chamber to the atmospheric pressure to deliver the substrate W to the atmospheric transfer module LM. The load lock modules LL1 to LL3 and the vacuum transfer module TM are partitioned from each other by openable/closable gate valves (not illustrated). The load lock modules LL1 to LL3 and the atmospheric transfer module LM are partitioned from each other by openable/closable gate valves (not illustrated).

The atmospheric transfer module LM is provided to face the vacuum transfer module TM. The atmospheric transfer module LM may be, for example, an equipment front end module (EFEM). The atmospheric transfer module LM has a rectangular shape in a plan view. The atmospheric transfer module LM includes an atmospheric transfer chamber. An interior of the atmospheric transfer chamber is maintained in an atmospheric pressure atmosphere. A transfer robot TR2 is provided in the interior of the atmospheric transfer chamber. The transfer robot TR2 is configured to be swingable, extendible, and movable up and down. Similar to the transfer robot TR1, the transfer robot TR2 includes two forks (an upper fork and a lower fork), which are capable of holding and transferring the substrate W. The transfer robot TR2 holds and transfers the substrate W between the load ports LP1 to LP4, the aligner AN, and the load lock modules LL1 to LL3. The atmospheric transfer module LM may also include a fan filter unit (FFU).

The load ports LP1 to LP4 are connected to the atmospheric transfer module LM. A plurality of substrate storage containers CS1 are placed on the load ports LP1 to LP4. The substrate storage container CS1 may be, for example, a front-opening unified pod (FOUP) that stores a plurality of substrates W (for example, 25 substrates).

The aligner AN is connected to the atmospheric transfer module LM. The aligner AN is configured to adjust a position of the substrate W. The aligner AN may be provided in an interior of the atmospheric transfer chamber.

The controller CU controls individual constituent elements of the substrate processing system PS. The controller CU controls, for example, an operation of the transfer robot TR1 provided in the vacuum transfer module TM, an operation of the transfer robot TR2 provided in the atmospheric transfer module LM, and opening/closing operations of the gate valves. The controller CU may be, for example, a computer. The controller CU includes a central processing unit (CPU), a random access memory (RAM), a read only memory (ROM), an auxiliary memory device, and the like. The CPU operates based on programs stored in the ROM or the auxiliary memory device to control the individual constituent elements of the substrate processing system PS.

### [Plasma Processing Apparatus]

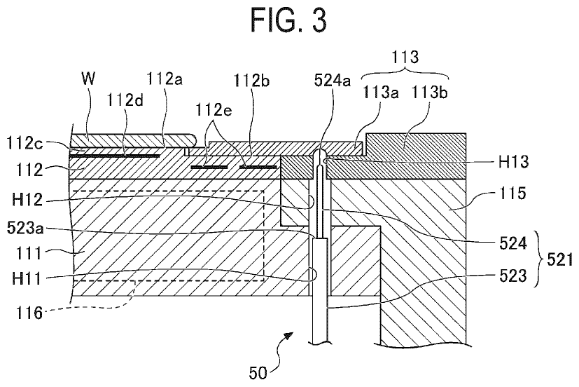

Referring to FIGS. 2 and 3, an example of a plasma processing apparatus 1 applied to the processing modules PM1 to PM7 of FIG. 1 will be described. FIG. 2 is a schematic cross-sectional view illustrating an example of the plasma processing apparatus 1. FIG. 3 is a partial enlarged view of FIG. 2.

The plasma processing apparatus 1 includes a plasma processing chamber 10, a gas supply 20, an RF power supply 30, an exhaust system 40, a lifter 50, and a controller 90.

The plasma processing chamber 10 includes the substrate support 11 and an upper electrode 12. The substrate support 11 is arranged in a lower region of a plasma processing space 10s in the plasma processing chamber 10. The upper electrode 12 is arranged above the substrate support 11 and functions as a portion of a ceiling plate of the plasma processing chamber 10.

The substrate support 11 supports the substrate W in the plasma processing space 10s. The substrate support 11 includes a lower electrode 111, an electrostatic chuck 112, the ring 113 (hereinafter, also referred to as “ring assembly 113”), and an insulating member 115. Further, the substrate support 11 includes a support temperature adjustment mechanism 116 for adjusting temperatures of the substrate W and the ring 113, which are supported on the substrate support 11.

The electrostatic chuck 112 is arranged on the lower electrode 111. The electrostatic chuck 112 has an upper surface composed of a substrate support surface 112a and a ring support surface 112b. The electrostatic chuck 112 supports the substrate W with the substrate support surface 112a. The electrostatic chuck 112 supports the inner ring 113a with the ring support surface 112b. The electrostatic chuck 112 includes an insulating member 112c, a first adsorption electrode 112d, and a second adsorption electrode 112e. The first and second adsorption electrodes 112d and 112e are embedded in the insulating member 112c. The first adsorption electrode 112d is located below the substrate support surface 112a. The electrostatic chuck 112 attracts and holds the substrate W on the substrate support surface 112a by applying a voltage to the first adsorption electrode 112d. The second adsorption electrode 112e is located below the ring support surface 112b. The electrostatic chuck 112 attracts and holds the inner ring 113a on the ring support surface 112b by applying a voltage to the second adsorption electrode 112e. In the example of FIGS. 2 and 3, the electrostatic chuck 112 includes a monopolar electrostatic chuck that attracts and holds the substrate W and a bipolar electrostatic chuck that attracts and holds the inner ring 113a. However, a bipolar electrostatic chuck may be used instead of the monopolar electrostatic chuck, or a monopolar electrostatic chuck may be used instead of the bipolar electrostatic chuck.

The ring assembly 113 includes the inner ring 113a and the outer ring 113b. The inner ring 113a has an annular shape. The inner ring 113a is arranged around the substrate W on an upper surface of a peripheral portion of the lower electrode 111. The inner ring 113a improves the uniformity of plasma processing on the substrate W. The inner ring 113a is formed of a conductive material such as silicon (Si) or silicon carbide (SiC). In addition, the inner ring 113a may be formed of an insulating material such as quartz. The outer ring 113b has an annular shape. The outer ring 113b is arranged on an outer peripheral portion of the inner ring 113a. The outer ring 113b protects an upper surface of the insulating member 115 from plasma, for example. The outer ring 113b is formed of, for example, an insulating material such as quartz. In addition, the outer ring 113b may be formed of a conductive material such as silicon or silicon carbide. In the illustrated example, an inner peripheral portion of the outer ring 113b is positioned inward of the outer peripheral portion of the inner ring 113a, and the outer peripheral portion of the inner ring 113a is positioned outward of the inner peripheral portion of the outer ring 113b, so that the inner and outer rings 113a and 113b partially overlap each other. In other words, the outer ring 113b is provided to surround the inner ring 113a and overlap the inner ring 113a from below in a plan view. Thus, when a plurality of support pins 521 (to be described later) is raised and lowered, the outer ring 113b and the inner ring 113a are integrally moved up and down. The insulating member 115 is arranged to surround the lower electrode 111. The insulating member 115 is fixed to a bottom of the plasma processing chamber 10 and support the lower electrode 111.

The support temperature adjustment mechanism 116 integrally adjusts the temperatures of the substrate W and the ring assembly 113. The support temperature adjustment mechanism 116 is provided inside the electrostatic chuck 112 (or inside the lower electrode 111 or the insulating member 115). The support temperature adjustment mechanism 116 may employ various structures such as a heater, a structure that circulates a heat-exchange medium from a heat-exchange-medium circulator (not illustrated), and a structure that supplies a heat-transfer gas from a gas supply/exhaust device (not illustrated).

The upper electrode 12 constitutes the plasma processing chamber 10 together with an insulating member 13. The upper electrode 12 supplies one or more types of processing gases from the gas supply 20 to the plasma processing space 10s. The upper electrode 12 includes a ceiling plate 121 and a support body 122. A lower surface of the ceiling plate 121 defines the plasma processing space 10s. The ceiling plate 121 is provided with a plurality of gas inlet ports 121a. Each of the plurality of gas inlet ports 121a penetrates the ceiling plate 121 in a plate thickness direction (vertical direction). The support body 122 detachably supports the ceiling plate 121. A gas diffusion chamber 122a is provided in an interior of the support body 122. A plurality of gas inlet ports 122b extend downward from the gas diffusion chamber 122a. The plurality of gas inlet ports 122b is in communication with the plurality of gas inlet ports 121a, respectively. The support body 122 is provided with a gas supply port 122c. The upper electrode 12 supplies one, or two or more processing gases from the gas supply port 122c to the plasma processing space 10s via the gas diffusion chamber 122a, the plurality of gas inlet ports 122b, and the plurality of gas inlet ports 121a.

A loading/unloading port 10p is provided in a sidewall of the plasma processing chamber 10. The substrate W is transferred between the plasma processing space 10s and the outside of the plasma processing chamber 10 via the loading/unloading port 10p. The loading/unloading port 10p is open or closed by the gate valve G.

The gas supply 20 includes one or more gas sources 21 and one or more flow rate controllers 22. The gas supply 20 supplies one or more types of processing gases from respective gas sources 21 to the gas supply port 122c via respective flow rate controllers 22. The flow rate controller 22 may include, for example, a mass flow controller or a pressure-controlled flow rate controller. The gas supply 20 may also include one or more flow rate modulation devices that modulate or pulse flow rates of one or more processing gases.

The RF power supply 30 includes two RF power supplies (a first RF power supply 31a and a second RF power supply 31b) and two matchers (a first matcher 32a and a second matcher 32b). The first RF power supply 31a supplies first RF power to the lower electrode 111 via the first matcher 32a. A frequency of the first RF power may be, for example, in a range of 13 MHz to 150 MHz. The second RF power supply 31b supplies second RF power to the lower electrode 111 via the second matcher 32b. A frequency of the second RF power may be, for example, in a range of 400 kHz to 13.56 MHz. Instead of the second RF power supply 31b, a DC power supply may be used.

The exhaust system 40 is connected to, for example, a gas exhaust port 10e provided at the bottom of the plasma processing chamber 10. The exhaust system 40 may include a pressure adjustment valve and a vacuum pump. An internal pressure of the plasma processing space 10s is adjusted by the pressure adjustment valve. The vacuum pump may include a turbo-molecular pump, a dry pump, or a combination thereof.

The lifter 50 includes a first lifter 51 and a second lifter 52.

The first lifter 51 includes a plurality of support pins 511 and an actuator 512. The plurality of support pins 511 is inserted into respective through-holes H1 formed in the lower electrode 111 and the electrostatic chuck 112, so that they are capable of moving up and down with respect to the upper surface of the electrostatic chuck 112. When the plurality of support pins 511 move upward from the upper surface of the electrostatic chuck 112, upper ends thereof come into contact with a lower surface of the substrate W to support the substrate W. The actuator 512 raises and lowers the plurality of support pins 511. The actuator 512 may include, for example, a motor such as a DC motor, a stepping motor, or a linear motor, an air-driven mechanism such as an air cylinder, a piezo actuator and the like. The first lifter 51 raises and lowers the plurality of support pins 511, for example, when transferring the substrate W between the transfer robot TR1 and the substrate support 11.

The second lifter 52 includes the plurality of support pins 521 and an actuator 522. Each support pin 521 is a stepped support pin formed of a cylindrical (solid rod-shaped) member. The support pin 521 includes a lower pin 523 and an upper pin 524. The upper pin 524 is provided on the lower pin 523. An outer diameter of the lower pin 523 is greater than that of the upper pin 524. As a result, a stepped portion is formed by an upper end surface 523a of the lower pin 523. The lower pin 523 and the upper pin 524 may be molded as a unit.

Each support pin 521 is inserted into a respective through-hole H11 formed in the lower electrode 111, a respective through-hole H12 formed in the insulating member 115, and a respective through-hole H13 formed in the outer ring 113b, so that the support pin 521 is capable of move upward and downward with respect to the upper surface of the insulating member 115 and the upper surface of the outer ring 113b. Inner diameters of the through-holes H11 and H12 are slightly greater than an outer diameter of the lower pin 523. An inner diameter of the through-hole H13 is slightly greater than an outer diameter of the upper pin 524 and smaller than the outer diameter of the lower pin 523.

The support pin 521 is displaceable between a standby position, a first support position, and a second support position.

The standby position is a position where an upper end surface 524a of the upper pin 524 is located lower than a lower surface of the inner ring 113a. When the support pin 521 is at the standby position, the inner ring 113a and the outer ring 113b are supported on the electrostatic chuck 112 and the insulating member 115, respectively, without being lifted by the support pins 521.

The first support position is a position higher than the standby position. The first support position is a position where the upper end surface 524a of the upper pin 524 protrudes upward from the upper surface of the outer ring 113b and also where the upper end surface 523a of the lower pin 523 is located lower than the lower surface of the outer ring 113b. When moving to the first support position, the support pin 521 brings the upper end surface 524a of the upper pin 524 into contact with a recess formed in the lower surface of the inner ring 113a to support the inner ring 113a.

The second support position is a position higher than the first support position. The second support position is a position where the upper end surface 523a of the lower pin 523 protrudes upward from the upper surface of the insulating member 115. When moving to the second support position, the support pin 521 brings the upper end surface 524a of the upper pin 524 into contact with the recess to support the inner ring 113a and also brings the upper end surface 523a of the lower pin 523 into contact with the lower surface of the outer ring 113b to support the outer ring 113b.

The actuator 522 raises and lowers the plurality of support pins 521. The actuator 522 may be similar in configured to the actuator 512.

The second lifter 52 raises the inner ring 113a by moving the plurality of support pins 521 to the first support position when delivering the inner ring 113a between the transfer robot TR1 and the substrate support 11. The second lifter 52 raises the inner ring 113a and the outer ring 113b by moving the plurality of support pins 521 to the second support position when delivering both the inner ring 113a and the outer ring 113b between the transfer robot TR1 and the substrate support 11. Alternatively, the second lifter 52 raises the outer ring 113b by moving the plurality of support pins 521 to the second support portion even when delivering the outer ring 113b between the transfer robot TR1 and the substrate support 11 in the absence of the inner ring 113a.

The controller 90 controls individual constituent elements of the plasma processing apparatus 1. The controller 90 includes, for example, a computer 91. The computer 91 includes, for example, a CPU 911, a memory 912, and a communication interface 913. The CPU 911 is configured to execute various control operations based on programs stored in the memory 912. The memory 912 includes at least one type of memory selected from a group consisting of auxiliary memory devices such as a RAM, a ROM, a hard disk drive (HDD), and a solid state drive (SSD). The communication interface 913 may communicate with the plasma processing apparatus 1 via a communication line such as a local area network (LAN). The controller 90 may be provided separately from the controller CU, or may be included in the controller CU.

### [Ring Storage Module]

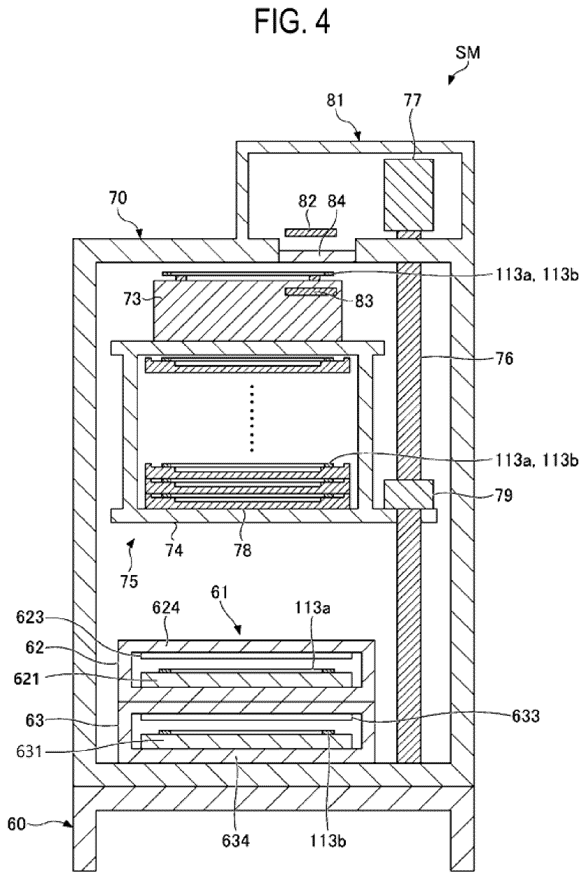

Referring to FIGS. 4 and 5, an example of the ring storage module RSM included in the substrate processing system PS of FIG. 1 will be described. FIG. 4 is a first schematic side cross-sectional view illustrating the ring storage module RSM. FIG. 5 is a second schematic side cross-sectional view of the ring storage module RSM as viewed in a direction orthogonal to that in FIG. 4.

The ring storage module RSM includes a chamber 70 provided on a frame 60 and a machine room 81 provided on the chamber 70. The chamber 70 is connected to an exhauster 72 via an exhaust port 71 provided in a bottom of the chamber 70, so that an internal pressure of the chamber 70 may be reduced by the exhauster 72. Further, the chamber 70 includes a gas source (not illustrated) that supplies an inert gas (for example, a N₂ gas) to adjust the internal pressure of the chamber 70. The machine room 81 is kept in, for example, an atmospheric pressure atmosphere.

The chamber 70 includes a storage 75 provided therein, which is capable of holding a plurality of inner rings 113a and a plurality of outer rings 113b. The storage 75 includes a stage 73 and a basket 74 provided below the stage 73. The storage 75 is movable up and down by a ball screw 76. The machine room 81 includes a line sensor 82, which detects a position, orientation, or the like of a member which is easy to wear, and a motor 77, which drives the ball screw 76. A window 84, which is made of quartz or the like, is provided in a partition between the chamber 70 and the machine room 81 so that the line sensor 82 receives light from a light emitting element 83, which will be described later.

The inner ring 113a or the outer ring 113b is placed on the stage 73. The stage 73 includes the light emitting element 83, which is located to face the line sensor 82 and does not rotate. The stage 73 is rotatable in a θ-direction to rotate the inner ring 113a or the outer ring 113b placed thereon to a predetermined orientation. In other words, the stage 73 and the line sensor 82 constitute a positioning device that performs alignment (positioning) of the inner ring 113a or the outer ring 113b. During the positioning, an orientation flat OF or notch of the inner ring 113a or the outer ring 113b is adjusted to a predetermined orientation. Further, during the positioning, central positions of the inner ring 113a and the outer ring 113b are aligned with each other.

The line sensor 82 detects an intensity of light emitted from the light emitting element 83 and outputs information about the detected light intensity to the controller CU. The line sensor 82 is configured to detect the inner ring 113a and the outer ring 113b and positions each of the inner ring 113a and the outer ring 113b. By using the face that the detected light intensity changes by the presence or absence of the orientation flat, the controller CU detects the orientation flat of the inner ring 113a or the outer ring 113b. The controller CU may be configured to perform the positioning of the inner ring 113a based on results obtained by detecting an inner portion of the line sensor 82 and to perform the positioning of the outer ring 113b based on results obtained by detecting an outer portion of the line sensor 82. Various light receiving elements such as a charge coupled device (CCD), a complementary metal oxide Semiconductor (CMOS), a photodiode, and the like may be used as the line sensor 82

In addition, the ring storage module RSM may use a position detection sensor, including an inner peripheral sensor that detects an inner peripheral position of the inner ring 113a or the outer ring 113b and an outer peripheral sensor that detects an outer peripheral position of the inner ring 113a or the outer ring 113b. Further, for example, the ring storage module RSM may use another optical sensor or a camera instead of the line sensor 82. In this case, the controller CU may use an image processing technique to calculate position information about the inner ring 113a or the outer ring 113b based on images captured by the camera.

The basket 74 is provided below the stage 73. One or more cassettes 78 are placed in an interior of the basket 74. The cassette 78 is a storage container that accommodates the inner ring 113a or the outer ring 113b and may be taken out from the basket 74. The cassette 78 is an open in front of the ring storage module RSM. The basket 74 holds the one or more cassettes 78 at intervals in the vertical direction.

In addition to the stage 73 and the basket 74, the storage 75 includes a guide 79 provided on a side surface thereof, which is supported by the ball screw 76. The ball screw 76 interconnects the upper and lower surfaces of the chamber 70 and passes through the upper surface of the chamber 70 so as to be connected to the motor 77 in the machine room 81. A through-hole in the upper surface of the chamber 70 is sealed such that the ball screw 76 may be rotated. The ball screw 76 is rotated by the motor 77 to move the storage 75 in the vertical direction (a Z-axis direction).

Further, the chamber 70 includes a temperature adjuster 61 provided therein to adjust the temperature of the inner ring 113a or the outer ring 113b. In the ring storage module RSM, the stage 73, the basket 74, and the temperature adjuster 61 are arranged vertically with respect to the vacuum transfer module TM. Thus, the transfer robot TR1 of the vacuum transfer module TM may easily access each height position of the ring storage module RSM.

The temperature adjuster 61 includes a first temperature adjustment device 62 and a second temperature adjustment device 63 to separately adjust the temperatures of one inner ring 113a and one outer ring 113b, respectively. For example, the first temperature adjustment device 62 is configured to adjust the temperature of the inner ring 113a, and the second temperature adjustment device 63 is configured to adjust the temperature of the outer ring 113b. In addition, according to processing situations of the temperature adjuster 61, the first temperature adjustment device 62 may adjust the temperature of the outer ring 113b, and the second temperature adjustment device 63 may adjust the temperature of the inner ring 113a. Further, the temperature adjuster 61 is not limited to being constituted with such a plurality of devices, and may be constituted with a single device. Similar to the storage 75, the temperature adjuster 61 may be configured to be movable in the vertical direction.

The first temperature adjustment device 62 includes an internal temperature adjustment room in which a stage 621 for placing the inner ring 113a thereon is provided. A shutter 622, which is capable of opening or closing the internal temperature adjustment room, is provided on a side surface of a housing 624 of the first temperature adjustment device 62. A temperature adjustment mechanism 623 is provided on an inner surface of the internal temperature adjustment room of the first temperature adjustment device 62, in an interior of the housing 624 or inside the stage 621. The second temperature adjustment device 63 includes an internal temperature adjustment room in which a stage 631 for placing the outer ring 113b thereon is provided. A shutter 632, which is capable of opening or closing the internal temperature adjustment room, is provided on a side surface of a housing 634 of the second temperature adjustment device 63. A temperature adjustment mechanism 633 is provided on an inner surface of the internal temperature adjustment room of the second temperature adjustment device 63, in an interior of the housing 634 or inside the stage 631.

The temperature adjustment mechanisms 623 and 633 may employ, for example, a heater for heating the ring 113, or a structure that supplies a temperature-adjusted gas toward the ring 113 to heat or cool the ring 113, together with an exhaust mechanism (not illustrated). Further, the stages 621 and 631, which respectively include the temperature adjustment mechanisms 623 and 633, may have an internal structure in which a temperature-adjusted heat exchange medium circulates to heat or cool the ring 113. The temperature adjustment mechanisms 623 and 633 adjust the temperature of the ring 113 within a range of 10 degrees C. from the temperature of the substrate support 11 of a processing module into which the ring 113 is to be loaded, among the processing modules PM1 to PM7. Alternatively, in the case in which the temperature adjustment mechanisms 623 and 633 are mechanisms in which the heat exchange medium circulates, they may adjust the temperature of the ring 113 within a range of 10 degrees C. from the temperature of the heat exchange medium circulating through a flow path of the substrate support 11 of a processing module into which the ring 113 is to be loaded, among the processing modules PM1 to PM7. For example, the temperature adjustment mechanisms 623 and 633 are configured to adjust the temperature of the ring 113 to a target temperature set by the controller CU within a range of −100 to 300 degrees C. In addition, for example, in a case in which all of the processing modules PM1 to PM7 perform such a temperature adjustment within a range of approximately 40 to 300 degrees C., the temperature adjustment mechanisms 623 and 633 may be configured to include a heater alone. The housings 624 and 634 are sized to accommodate only one ring 113 (either the inner ring 113a or the outer ring 113b), which rapidly implements the temperature adjustment.

The first temperature adjustment device 62 and the second temperature adjustment device 63 may include a gas supply/exhaust mechanism (not illustrated) separately from the temperature adjustment mechanisms 623 and 633. The gas supply/exhaust mechanism supplies and exhausts a gas to and from the internal temperature adjustment room to remove deposits such as reaction products adhering to the inner ring 113a or the outer ring 113b used in the processing modules PM1 to PM7. In other words, by the gas supplied to the internal temperature adjustment room by the gas supply/exhaust mechanism, the deposits volatilized by thermal decomposition or chemical reactions are exhausted from the internal temperature adjustment room. In addition, in a case in which a structure that supplies and exhausts a temperature-adjusted gas is employed to each of the temperature adjustment mechanisms 623 and 633, the deposits may be discharged by the supply and exhaust of the temperature-adjusted gas.

The ring storage module RSM is detachably connected to the vacuum transfer module TM via the gate valve G. The chamber 70 is configured such that the upper fork FK1 and the lower fork FK2 of the transfer robot TR1 in the vacuum transfer module TM move via the gate valve G. The upper fork FK1 and the lower fork FK2 perform the loading/unloading of the inner ring 113a or the outer ring 113b into/from the cassette 78, the loading/unloading of the inner ring 113a or the outer ring 113b into/from the stage 73, and the loading/unloading of the inner ring 113a or the outer ring 113b into/from the temperature adjuster 61.

The door 80 is open or closed, for example, when taking out the cassette 78 from the chamber 70, or when installing the cassette 78 into the chamber 70.

A light emitting element 85 and a sheet count detection sensor 86 detect the number of inner rings 113a or outer rings 113b placed in the cassette 78 during the movement of the storage 75. The light emitting element 85 is, for example, a light emitting diode (LED) or a semiconductor laser. The sheet count detection sensor 86 detects an intensity of light emitted from the light emitting element 85 and outputs information about the detected light intensity to the controller CU. The controller CU detects the number of inner rings 113a or outer rings 113b by counting the number of times the light emitted from the light emitting element 85 is blocked based on the detected light intensity. The sheet count detection sensor 86 may be, for example, a CCD, CMOS, photodiode, or phototransistor.

The controller CU recognizes arrangements, quantities, and conditions (for example, a new one or a used one) of the inner rings 113a or the outer rings 113b stored in each cassette 78 of the ring storage module RSM. Further, the controller CU determines whether or not to replace the inner ring 113a or the outer ring 113b with a new one based on triggers such as user's instructions, the number of rounds of substrate processing, the quality of the substrate W, sensor values in the respective processing modules PM1 to PM7, and the occurrence of errors. When it is determined that the replacement is necessary, the controller CU retrieves the ring 113 (the inner ring 113a or the outer ring 113b) to be replaced from a processing module, and performs processing using the ring 113 for replacement stored in the ring storage module RSM.

Further, in the substrate processing system PS, the temperature adjuster 61 is provided in the ring storage module RSM to adjust the temperature of the ring 113 (the inner ring 113a or the outer ring 113b) before the ring 113 is transferred to the respective processing modules PM1 to PM7. This makes it possible to reduce a time required for adjusting the temperature of the ring 113 in the respective processing modules PM1 to PM7, which enhances the overall productivity of the substrate processing system PS. When setting the ring 113 in the respective processing modules PM1 to PM7, the controller CU manages factors such as a transfer timing, a transfer position of the ring 113, a temperature (temperature adjustment period) and the like to place the ring 113 in a specified processing module among the respective processing modules PM1 to PM7.

[Transfer Method]

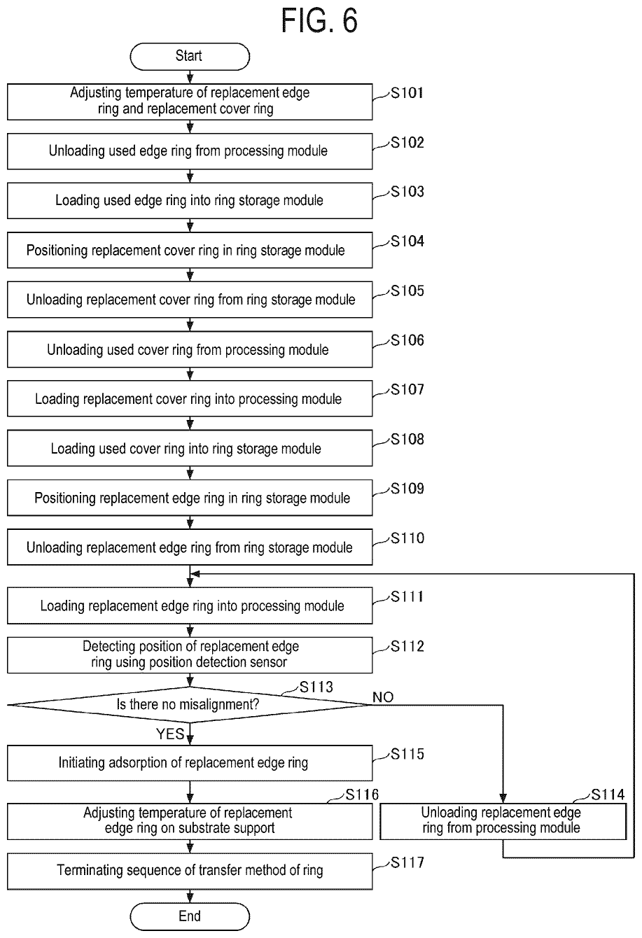

FIG. 6 is a flowchart illustrating a transfer method of a first example. Next, referring to FIG. 6, the transfer method of placing the ring 113 in a desired processing module will be described. In addition, hereinafter, a case of transferring the ring 113 between the ring storage module RSM and the processing module PM1 will be described. Even if the target processing module to be replaced is one of the other processing modules PM2 to PM7, the same method as that used when the processing module for replacement target is the processing module PM1 may be applied.

The transfer method of the first example is a method including replacing both an edge ring FR and a cover ring CR, which constitute the ring 113, with new ones in the substrate processing system PS. The edge ring FR corresponds to the inner ring 113a illustrated in FIG. 3. The cover ring CR corresponds to the outer ring 113b illustrated in FIG. 3. The cover ring CR is an example of a first ring, and the edge ring FR is an example of a second ring.

The transfer method of the first example is initiated, for example, when both the edge ring FR and the cover ring CR are to be replaced with new ones. The transfer method of the first example is performed in a state where there is no substrate W in the processing module PM1 and the loading/unloading and processing of the substrate W are stopped.

The transfer method of the first example includes Operations S101 to S117. Operations S101 to S117 are executed when the controller CU controls the individual constituent elements of the substrate processing system PS.

In Operation S101, the controller CU adjusts the temperatures of the edge ring FR for replacement (hereinafter sometimes simply referred to as a “replacement edge ring FR”) and the cover ring CR for replacement (hereinafter sometimes simply referred to as a “replacement cover ring CR”). In addition, the replacement edge ring FR may be either a new (unused) one or one which was used but not worn so much. The replacement cover ring CR may be either a new (unused) one or one which was used but not worn so much.

In Operation S101, the controller CU may include determining whether or not the ring 113 needs to be replaced with a new one, and determining whether or not the replacement of the ring 113 is possible. Whether or not the ring 113 needs to be replaced with a new one may be determined based on the aforementioned triggers. The controller CU may determine whether or not the replacement is possible based on factors such as the presence or absence of the substrate W in the processing module PM1 for replacement target, a transfer schedule of the transfer robot TR1 and the like. In addition, when it is determined that the substrate W presents in the processing module PM1 or the transfer robot TR1, the controller CU may control the transfer robot TR1 to transfer the substrate W from the vacuum transfer module TM to the load lock modules LL1 to LL3, and then control the transfer robot TR1 to stop the transfer of the substrate W.

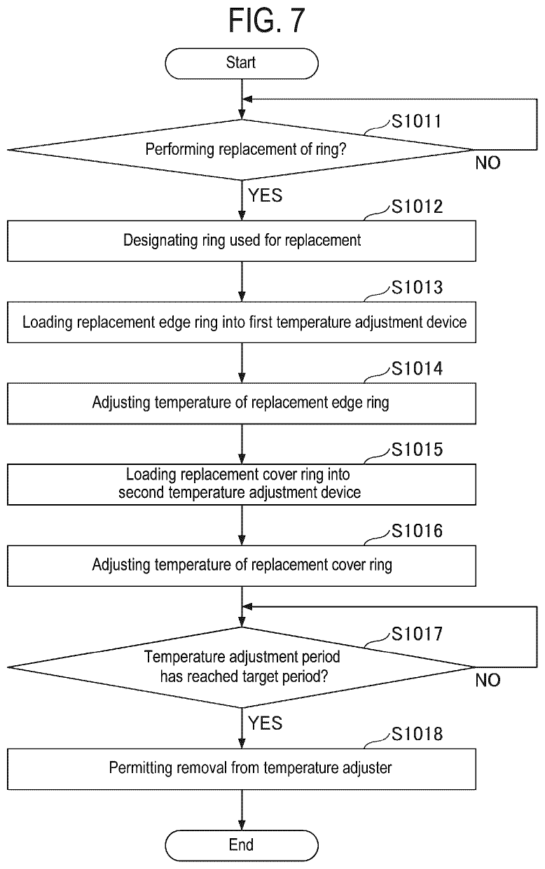

FIG. 7 is a flowchart illustrating an example of a procedure of Operation S101. In Operation S1011, the controller CU first determines whether or not to perform the replacement of the ring 113 (whether or not the replacement is necessary and whether or not the replacement is possible). When it is determined that the replacement of the ring 113 is not necessary (NO in Operation S1011), the controller CU repeats Operation S1011. On the other hand, when it is determined that the replacement of the ring 113 is necessary (YES in Operation S1011), the controller CU proceeds to Operation S1012.

In Operation S1012, the controller CU specifies rings to be newly used among the replacement edge rings FR and the replacement cover rings CR stored in each cassette 78 of the ring storage module RSM. Then, when the replacement edge ring FR and the replacement cover ring CR, which are to be newly used, are specified, the controller CU proceeds to an operation of adjusting the temperatures of these rings by the temperature adjuster 61.

In Operation S1013, the controller CU operates the transfer robot TR1 based on a position of the specified replacement edge ring FR. For example, the controller CU controls the upper fork FK1 to take out the replacement edge ring FR and load the same into the first temperature adjustment device 62. In Operation S1014, the controller CU performs a control to place the replacement edge ring FR on the stage 621 of the first temperature adjustment device 62, close the shutter 622, and then adjust the temperature of the replacement edge ring FR to a target temperature by the temperature adjustment mechanism 623. The target temperature is, for example, the same as the temperature of the substrate support 11 in the processing module PM1 for replacement target (the internal temperature of the plasma processing chamber 10). Thus, the temperature of the replacement edge ring FR may be appropriately adjusted before the replacement edge ring FR is transferred to the processing module PM1.

Similarly, in Operation S1015, the controller CU operates the transfer robot TR1 based on a position of the specified replacement cover ring CR. For example, the controller CU controls the lower fork FK2 to take out the replacement cover ring CR and load the same into the second temperature adjustment device 63. In Operation S1016, the controller CU performs a control to place the replacement cover ring CR on the stage 631 of the second temperature adjustment device 63, close the shutter 632, and then adjust the temperature of the replacement cover ring CR to a target temperature by the temperature adjustment mechanism 633. The target temperature is set to be the same as a target temperature of the replacement edge ring FR in the first temperature adjustment device 62. Thus, the temperature of the replacement cover ring CR may be appropriately adjusted before the replacement cover ring CR is transferred to the processing module PM1.

Further, the controller CU measures a temperature adjustment period when adjusting the temperature of the replacement edge ring FR and the temperature of the replacement cover ring CR, and monitors whether or not the measured temperature adjustment period has reached a preset target period (Operation S1017). Then, when the temperature adjustment period is determined to exceed the preset target period, the controller CU recognizes that the temperature adjustment of the replacement edge ring FR and the temperature adjustment of the replacement cover ring CR are completed, and permits removal of these rings from the temperature adjuster 61 (Operation S1018). In addition, the completion of the temperature adjustment of the replacement edge ring FR and temperature adjustment of the replacement cover ring CR may be recognized by various methods. For example, temperature sensors (not illustrated) may be installed inside the first temperature adjustment device 62 and the second temperature adjustment device 63. When the temperatures of the replacement edge ring FR and the replacement cover ring CR detected by these temperature sensors have reached the target temperature, the completion of the temperature adjustments may be recognized. The target temperature may be set within a range of 10 degrees C. from the temperature of the substrate support 11 in a processing module into which the ring 113 is to be loaded, or within a range of 10 degrees C. from the temperature of the heat exchange medium circulating through the flow path of the substrate support 11 in a processing module into which the ring 113 is to be loaded.

While the temperature adjustment of the replacement edge ring FR and the replacement cover ring CR is being performed by the temperature adjuster 61, the controller CU may perform other operations of the transfer method, or the transfer of the substrate W with respect to the other processing modules PM2 to PM7 or the load lock modules LL1 to LL3. This makes it possible to further enhance the overall efficiency of the operation of the substrate processing system PS.

Further, it is desirable to perform the temperature adjustment of the replacement edge ring FR and the temperature adjustment of the replacement cover ring CR as quickly as possible when the replacement of the ring 113 is determined to be necessary. Thus, the replacement edge ring FR or the replacement cover ring CR, the temperatures of which have been adjusted, may be more rapidly loaded into the processing module PM1. Therefore, when the replacement of the ring 113 is determined to be necessary, the controller CU may preferentially execute the loading of the replacement edge ring FR or the replacement cover ring CR into the temperature adjuster 61 by the transfer robot TR1. For example, even if the substrate W is scheduled to be transferred from the load lock modules LL1 to LL3 to the processing modules PM2 to PM7, the controller CU may preferentially execute Operation S101 (in an interrupt manner) to perform the transfer and temperature adjustment of the ring 113. Further, as will be described later, when loading the ring 113 into the processing module PM1, the replacement cover ring CR is first loaded, and then, the replacement edge ring FR is loaded. Therefore, the controller CU may preferentially load the replacement cover ring CR into the temperature adjuster 61 to initiate the temperature adjustment of the replacement cover ring CR.

Returning to FIG. 6, in Operation S102, the controller CU causes the transfer robot TR1 to unload, from the processing module PM1, the edge ring FR (hereinafter sometimes referred to as a “used edge ring FR”), which was used during the substrate processing while being placed on the substrate support 11 of the processing module PM1.

In Operation S103, the controller CU causes the transfer robot TR1 to load the used edge ring FR, which was unloaded from the processing module PM1 in Operation S102, into the ring storage module RSM. At this time, the transfer robot TR1 stores the used edge ring FR in an empty cassette 78 among the plurality of cassettes 78.

In Operation S104, the controller CU performs alignment (positioning) on the replacement cover ring CR using the stage 73 of the ring storage module RSM (see FIG. 5). Accordingly, the temperature adjustment of the replacement cover ring CR by the temperature adjuster 61 is completed at least before Operation S104 begins. In addition, the replacement cover ring CR is preferentially loaded into the processing module PM1 so that the temperature of the replacement cover ring CR is adjusted in the processing module PM1. Therefore, the target temperature in the temperature adjustment of the replacement cover ring CR may be lower than that in the temperature adjustment of the replacement edge ring FR.

When performing the positioning, the controller CU causes the transfer robot TR1 to take out the replacement cover ring CR, the temperature of which has been adjusted, from the second temperature adjustment device 63 of the ring storage module RSM and place the same on the stage 73 of the ring storage module RSM. As described above, the positioning of the replacement cover ring CR is performed by rotating the stage 73 while monitoring the line sensor 82, so that the orientation flat of the replacement cover ring CR is aligned to a predetermined orientation.

In Operation S105, the controller CU causes the transfer robot TR1 to take out the replacement cover ring CR, which has subjected to the positioning in Operation S104, from the stage 73 and unload the same from the ring storage module RSM.

In Operation S106, the controller CU causes the transfer robot TR1, while holding the replacement cover ring CR unloaded from the ring storage module RSM, to unload, from the processing module PM1, the cover ring CR (hereinafter sometimes referred to as a “used cover ring CR”), which was used during the substrate processing while being placed on the substrate support 11 of the processing module PM1. At this time, for example, the transfer robot TR1 holds the replacement cover ring CR with the upper fork FK1, and holds the used cover ring CR with the lower fork FK2. However, such a holding manner performed by the transfer robot TR1 may be exchanged.

In Operation S107, the controller CU causes the transfer robot TR1 to load the replacement cover ring CR held by the transfer robot TR1 into the processing module PM1. When the replacement cover ring CR is held by the upper fork FK1 and the used cover ring CR is held by the lower fork FK2, the replacement cover ring CR is located higher than the used cover ring CR. Therefore, even if particles or the like adhering to the used cover ring CR fall, the particles may be prevented from adhering to the replacement cover ring CR.

In Operation S108, the controller CU causes the transfer robot TR1 to load the used cover ring CR, which was unloaded from the processing module PM1, into the ring storage module RSM. At this time, the transfer robot TR1 stores the used cover ring CR in an empty cassette 78 among the plurality of cassettes 78.

In Operation S109, the controller CU performs the alignment (positioning) on the replacement edge ring FR using the stage 73 of the ring storage module RSM (see FIG. 5). Accordingly, the temperature adjustment of the replacement edge ring FR by the temperature adjuster 61 is completed before the replacement edge ring FR is taken out from the temperature adjuster 61 and is subjected to the positioning (before Operation S109).

The controller CU causes the transfer robot TR1 to take out the replacement edge ring FR, the temperature of which has been adjusted, from the first temperature adjustment device 62 of the ring storage module RSM and place the same on the stage 73 of the ring storage module RSM. Similar to the replacement cover ring CR, the positioning of the replacement edge ring FR is performed by rotating the stage 73 while monitoring the line sensor 82, so that the orientation flat of the replacement edge ring FR is aligned to a predetermined orientation.

In Operation S110, the controller CU causes the transfer robot TR1 to take out the replacement edge ring FR, which has subjected to the positioning in Operation S109, from the stage 73 and unload the same from the ring storage module RSM.

In Operation S111, the controller CU causes the transfer robot TR1 to load the replacement edge ring FR, which is unloaded from the ring storage module RSM, into the processing module PM1.

In Operation S112, the controller CU operates the transfer robot TR1 to detect a position of the replacement edge ring FR placed on the substrate support 11 using the position detection sensor S1 of the upper fork FK1 (or the position detection sensor S2 of the lower fork FK2).

In Operation S113, the controller CU determines whether or not misalignment occurs in the replacement edge ring FR based on the detected position of the replacement edge ring FR. When the misalignment is determined to occur in the replacement edge ring FR (NO in Operation S113), the controller CU proceeds to Operation S114. When no misalignment is determined to occur in the replacement edge ring FR (YES in Operation S113), the controller CU proceeds to Operation S115.

In Operation S114, the controller CU causes the transfer robot TR1 to unload the replacement edge ring FR from the processing module PM1. After Operation S114, the controller CU returns to Operation S111 where the position of the replacement edge ring FR, which is unloaded from the processing module PM1 is corrected by the transfer robot TR1. Thereafter, the replacement edge ring FR, the position of which has been corrected in Operation S111, is loaded into the processing module PM1.

In Operation S115, the controller CU initiates the attraction and holding of the replacement edge ring FR by the electrostatic chuck 112.

In Operation S116, the controller CU causes the support temperature adjustment mechanism 116 of the substrate support 11 to adjust the temperature of the ring 113 (the replacement edge ring FR). Through the above-described process flow, the temperature of the replacement edge ring FR is adjusted in advance by the temperature adjuster 61. Therefore, the controller CU may significantly shorten a time required to execute Operation S116.

In Operation S117, the controller CU terminates a sequence of the transfer method for the ring 113. Thereafter, the controller CU may load the substrate W into the processing module PM1 in which the replacement edge ring FR and the replacement cover ring CR are accommodated, and may perform the substrate processing on the substrate W in a satisfactory manner.

As described above, according to the transfer method of the first example, the temperature of the ring 113 (the replacement edge ring FR and the replacement cover ring CR) is adjusted by the temperature adjuster 61 before the ring 113 is loaded into the processing module PM1. According to the substrate processing system PS configured as above, it is possible to shorten a time required to adjust the temperature of the ring 113 in the processing module PM1. As a result, the substrate processing system PS may quickly initiate the substrate processing by the processing module PM1, thereby enhancing the productivity of the substrate processing. Further, as described above, the substrate processing system PS adjusts the temperature of the ring 113 within a range of 10 degrees C. from the temperature of the substrate support 11 or the temperature of the heat exchange medium circulating through the flow path of the substrate support 11, and places the ring 113 on the electrostatic chuck 112 of the substrate support 11 such that the ring 113 is electrostatically attracted onto the electrostatic chuck 112. With this configuration, it is possible to reduce friction from being caused by thermal expansion difference or thermal shrinkage difference, which is caused by a large difference in temperature between the ring 113 and the electrostatic chuck 112 during the electrostatic attraction in the processing module PM1. This makes it possible to suppress particles from being generated due to such a friction.

In addition, the transfer method may execute some of Operations S101 to S117 illustrated in FIG. 6 in a changed order.

For example, Operation S106 may be performed between Operation S102 and Operation S103. Operations S106 and S108 may be performed between Operation S103 and Operation S104, or between Operation S104 and Operation S105. Alternatively, Operations S106 and S108 may be performed in parallel with Operation S104. Operation S108 may be performed between Operation S106 and Operation S107.

Further, a timing at which Operation S109 is performed is not particularly limited as long as the temperature adjustment of the replacement edge ring FR by the temperature adjuster 61 has been completed. Operation S109 may be performed between Operation S105 and Operation S106, between Operation S106 and Operation S107, or between Operation S107 and Operation S108. Alternatively, Operation S109 may be performed in parallel with at least one of Operation S106, Operation S107, or Operation S108.

Further, some of Operations S101 to S117 illustrated in FIG. 6 may be omitted. For example, in a configuration in which the edge ring FR is not attracted and held by the electrostatic chuck 112, Operation S115 may be omitted.

Further, additional operations may be added to Operations S101 to S117 illustrated in FIG. 6. For example, after the transfer robot TR1 loads the replacement cover ring CR into the processing module PM1 in Operation S107, an operation of determining whether or not misalignment occurs in the replacement cover ring CR, and an operation of correcting the position of the replacement cover ring CR may be performed, similar to Operations S112, S113, and S114.

Further, in the above embodiments, the example in which the temperature of the replacement edge ring FR or the replacement cover ring CR are adjusted, subsequently, the alignment is performed on the replacement edge ring FR or the replacement cover ring CR, and the replacement edge ring FR or the replacement cover ring CR is transferred to the processing module, has been described. However, the substrate processing system PS and the transfer method may have a configuration in which the replacement edge ring FR or the replacement cover ring CR is subjected to the alignment, transferred to the temperature adjuster 61 where the temperature of the replacement edge ring FR or the replacement cover ring CR is adjusted, and subsequently, the replacement edge ring FR or the replacement cover ring CR is transferred to the processing module. However, in the latter case, since the loading and unloading of the ring into and from the temperature adjuster 61 is performed after the alignment, it is preferable to sequentially perform the temperature adjustment by the temperature adjuster 61, the alignment, and the transfer of the replacement edge ring FR or the replacement cover ring CR to the processing module.

Further, when the controller CU determines that the replacement edge ring FR is misaligned, it is not necessary to unload the replacement edge ring FR from the processing module PM1 in Operation S114. In other words, the controller CU may cause the transfer robot TR1 to correct the position of the replacement edge ring FR based on an amount of misalignment inside the processing module PM1 and place the replacement edge ring FR on the substrate support 11.

Further, the substrate processing system PS and the transfer method are not limited to the above-described configuration in which two members (the edge ring FR and the cover ring CR) constituting the ring 113 are transferred but may have a configuration in which one ring 113 is transferred. The substrate processing system PS and the transfer method may have a configuration in which temperatures of two rings are simultaneously adjusted by the temperature adjuster 61, and the two rings are simultaneously unloaded from the temperature adjuster 61, and simultaneously loaded into a processing module for replacement target. The substrate processing system and the transfer method may have a configuration in which a single temperature adjuster 61 adjusts the temperatures of two rings at different timings and loads them separately into a processing module for replacement target.

Further, the temperature adjuster 61 may be provided at a different position in the ring storage module RSM. For example, the temperature adjuster 61 may be provided upward of the stage 73 in the vertical direction, or may be provided between the stage 73 and the basket 74. As an example, the temperature adjuster 61 may be configured integrally with the positioning device by providing a temperature adjustment mechanism inside the stage 73.

Further, the substrate processing system PS and the transfer method may have a configuration in which the temperature adjuster 61 is provided at a position different from the ring storage module RSM, and the transfer robot TR1 transfers the ring 113 to the temperature adjuster 61. The temperature adjuster 61 provided separately from the ring storage module RSM may be connected to the exterior of the vacuum transfer module TM, or may be arranged inside the vacuum transfer module TM. Alternatively, the temperature adjuster 61 may be provided in the load lock modules LL1 to LL3. In other words, in the substrate processing system PS, a temperature adjustment mechanism may be provided in the load lock modules LL1 to LL3 and the ring 113 may be transferred to the load lock modules LL1 to LL3 where the temperature of the ring 113 may be adjusted by the temperature adjustment mechanism.

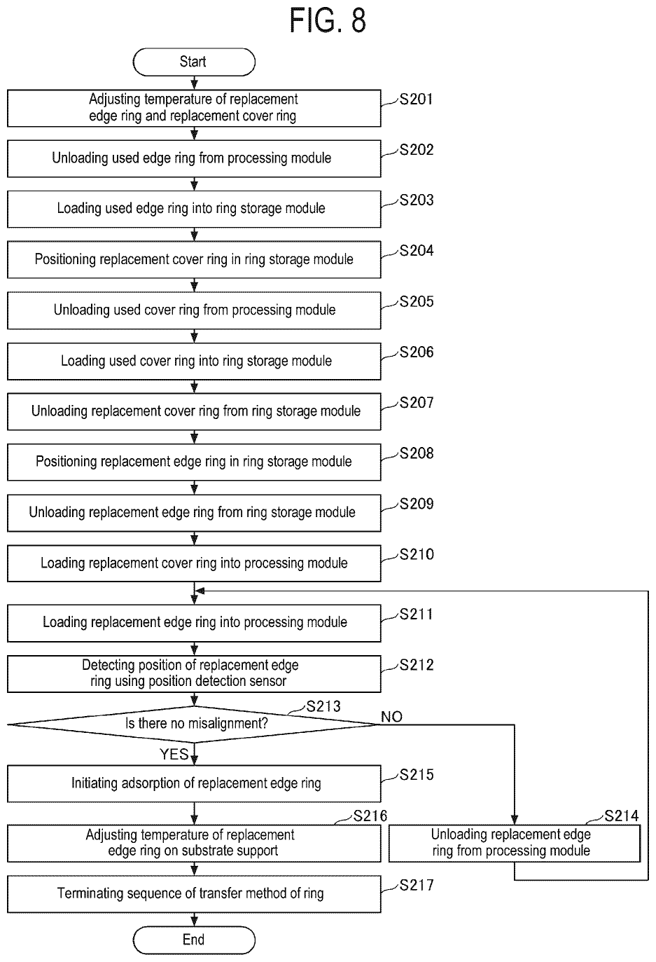

FIG. 8 is a flowchart illustrating a transfer method of a second example. The transfer method of the second example is also a method of replacing both the edge ring FR and the cover ring CR with new ones in the substrate processing system PS. The transfer method of the second example is performed in a state where no substrate W is provided in the processing module PM1 and the loading/unloading and processing of the substrate W are stopped. In addition, even in the transfer method of the second example, a case of transferring the ring 113 between the ring storage module RSM and the processing module PM1 will be described. Even when the processing module for replacement target is one of the other processing modules PM2 to PM7, the same method as that used when the processing module for replacement target is the processing module PM1 may be applied.

The transfer method of the second example includes Operations S201 to S217. Operations S201 to S217 are performed by the controller CU configured to control the individual constituent elements of the substrate processing system PS.

Operations S201 to S204 may be similar to Operations S101 to S104.

In Operation S205, the controller CU causes the transfer robot TR1 to unload the used cover ring CR from the processing module PM1.

In Operation S206, the controller CU causes the transfer robot TR1 to load the used cover ring CR, which is unloaded from the processing module PM1 in Operation S205, into the ring storage module RSM.

In Operation S207, the controller CU causes the transfer robot TR1 to take out the replacement cover ring CR, which has been subjected to the positioning in Operation S204, from the stage 73 and unload the same from the ring storage module RSM.

In Operation S208, the controller CU performs the alignment (positioning) on the replacement edge ring FR using the stage 73 of the ring storage module RSM (see FIG. 5). Accordingly, the temperature adjustment of the replacement edge ring FR by the temperature adjuster 61 is completed before the replacement edge ring FR is taken out from the temperature adjuster 61 and is subjected to the alignment (before Operation S208).

In Operation S209, the controller CU causes the transfer robot TR1 to unload the replacement edge ring FR, which has been subjected to the positioning in Operation S209, from the ring storage module RSM.

In Operation S210, the controller CU causes the transfer robot TR1 to load the replacement cover ring CR heled by the transfer robot TR1 into the processing module PM1.

Operations S211 to S217 may be similar to Operations S111 to S117.

As described above, even in the transfer method of the second example, the temperature of the ring 113 (the replacement edge ring FR and the replacement cover ring CR) may be adjusted by the temperature adjuster 61 before the ring 113 is loaded into the processing module PM1. This improves the productivity of substrate processing. In particular, in the transfer method of the second example, the transfer robot TR1 does not simultaneously hold the used edge ring FR, the used cover ring CR, the replacement edge ring FR, and the replacement cover ring CR. This makes it possible to suppress particles from adhering to the replacement edge ring FR and the replacement cover ring CR.

In addition, similar to the transfer method of the first example, even in the transfer method of the second example, the orders of some of Operations S201 to S217 illustrated in FIG. 8 may be changed, some of Operations may be omitted, or other Operations may be added.

For example, Operations S205 and S206 may be performed between Operation S202 and Operation S203, or between Operation S203 and Operation S204. Further, for example, in a case in which the edge ring FR is not attracted and held by the electrostatic chuck 112, Operation S215 may be omitted. For example, after the transfer robot TR1 loads the replacement cover ring CR into the processing module PM1 in Operation S210, the position of the replacement cover ring CR may be corrected when the misalignment is determined to occur in the replacement cover ring CR, similar to Operations S212, S213, and S214.

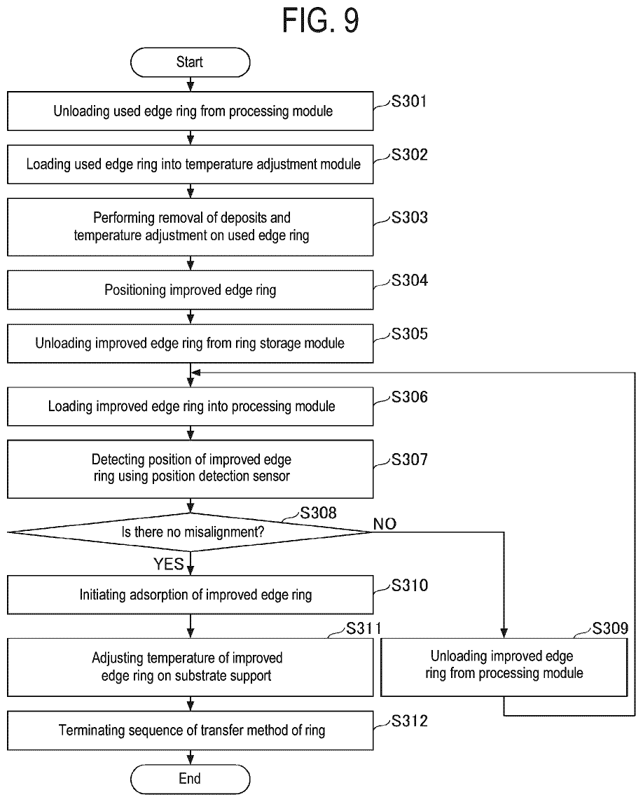

FIG. 9 is a flowchart illustrating a transfer method of a third example. The transfer method of the third example is a method including heating the edge ring FR used in the processing modules PM1 to PM7 by the temperature adjuster 61 to remove deposits such as reaction products adhering to the edge ring FR, and returning the edge ring FR, from which the deposits have been removed (hereinafter sometimes referred to as an “improved edge ring FR”), to the processing modules PM1 to PM7. The controller CU initiates the transfer method of the third example based on triggers such as user's instructions, the number of substrate processing, a quality of the substrate W, sensor values in the respective processing modules PM1 to PM7, the occurrence of errors and the like. In this case, the controller CU specifies a processing module in which the edge ring FR is to be processed. In addition, even in the transfer method of the third example, a case of transferring the edge ring FR between the ring storage module RSM and the processing module PM1 will be described. Even when the processing module is one of the other processing modules PM2 to PM7, the same method as that used when the processing module is the processing module PM1 may be applied.

The transfer method of the third example includes Operations S301 to S312 as illustrated in FIG. 9. Operations S301 to S312 are performed by the controller CU configured to control the individual constituent elements of the substrate processing system PS.

In Operation S301, the controller CU causes the transfer robot TR1 to unload the used edge ring FR (the edge ring FR to which deposits adhere), which was used during the substrate processing while being placed on the substrate support 11 of the processing module PM1, from the processing module PM1.

In Operation S302, the controller CU causes the transfer robot TR1 to load the used edge ring FR, which is unloaded from the processing module PM1, into the temperature adjuster 61 of the ring storage module RSM (for example, the first temperature adjustment device 62).

In Operation S303, the controller CU causes the temperature adjuster 61 to heat the used edge ring FR loaded thereinto and adjust the temperature thereof. Removing the deposits by the temperature adjuster 61 may be implemented by a known method including heating the edge ring FR to a temperature at which the deposits may be removed (for example, heating the edge ring FR to approximately 300 degrees C.), supplying a gas (including a temperature-adjusted gas) that reacts with the deposits into the internal temperature adjustment room, or the like. The temperature adjuster 61 may adopt a configuration in which, in addition to the temperature adjustment mechanisms 623 and 633, a purge gas source (not illustrated) supplies a purge gas to remove the deposits, or a plasma generator (not illustrated) generates plasma in the internal temperature adjustment room to remove the deposits. As a result, the deposits adhering to the edge ring FR may be removed at good level. In particular, when the temperature adjuster 61 has a gas exhaust configuration, volatile substances from the deposits formed in the internal temperature adjustment room may be smoothly discharged. Accordingly, the edge ring FR with reduced deposits (hereinafter sometimes referred to as an “improved edge ring FR”) may be obtained.

After the removal of the deposits, the temperature adjuster 61 proceeds to an operation of adjusting the temperature of the improved edge ring FR as a pre-processing operation before returning the improved edge ring FR to the processing module PM1. In a case in which the improved edge ring FR is heated during the removal of the deposits, which has been performed previously, the temperature adjuster 61 may supply a temperature-adjusted gas such as an inert gas to the internal temperature adjustment room and exhaust the gas, or may circulate a temperature-adjusted heat exchange medium in the interiors of the stages 621 and 631 on which the ring 113 is placed, to promote dissipation of heat from the improved edge ring FR. These operations may be performed simultaneously. In addition, the temperature adjuster 61 may perform a control to merely stop the heating of the improved edge ring FR. An inert gas, the temperature of which has not been adjusted, may be merely supplied into the internal temperature adjustment room. A target temperature of the improved edge ring FR at this time may be set within a range of 10 degrees C. from the temperature of the substrate support 11 of a processing module into which the ring 113 is to be loaded, or within a range of 10 degrees C. from the temperature of the heat exchange medium circulating through the flow path of the substrate support 11 of a processing module into which the ring 113 is to be loaded.

In Operation S304, the controller CU causes the transfer robot TR1 to take out the improved edge ring FR, the temperature of which has been adjusted, from the temperature adjuster 61 and place the same on the stage 73 of the ring storage module RSM, and performs the alignment (positioning) on the improved edge ring FR.

Operations S305 to S312 may be similar to Operations S110 to S117 illustrated in FIG. 6.

As described above, according to the transfer method of the third example, the temperature adjuster 61 removes the deposits adhering to the ring 113 (the edge ring FR) and adjusts the temperature of the ring 113, which makes it possible to improve the productivity of the substrate processing. Thus, in the substrate processing system PS, the operation of removing the deposits adhering to the edge ring FR in the processing modules PM1 to PM7 may be omitted. This makes it possible to suppress contamination (such as scattering of particles) from occurring in the processing modules PM1 to PM7 due to the removal of the deposits, which results in an increase in quality of the substrate processing.

In addition, similar to the transfer method of the first example, even in the transfer method of the third example, the orders of some of Operations S301 to S312 illustrated in FIG. 9 may be changed, some of Operations may be omitted, or other Operations may be added. For example, Operation S304 may be performed between Operation S301 and Operation S302. Further, for example, Operation S310 may be omitted in a case in which the edge ring FR is not attracted and held by the electrostatic chuck 112.

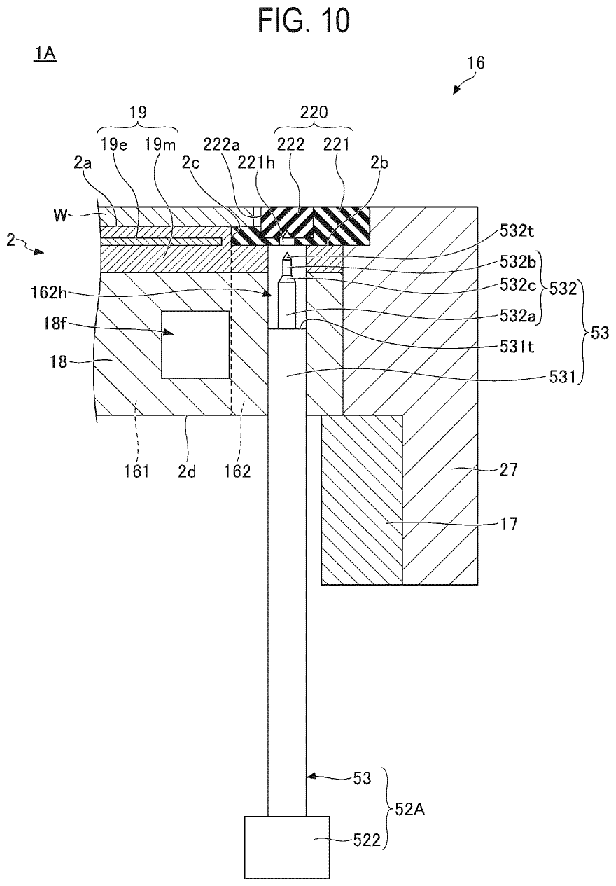

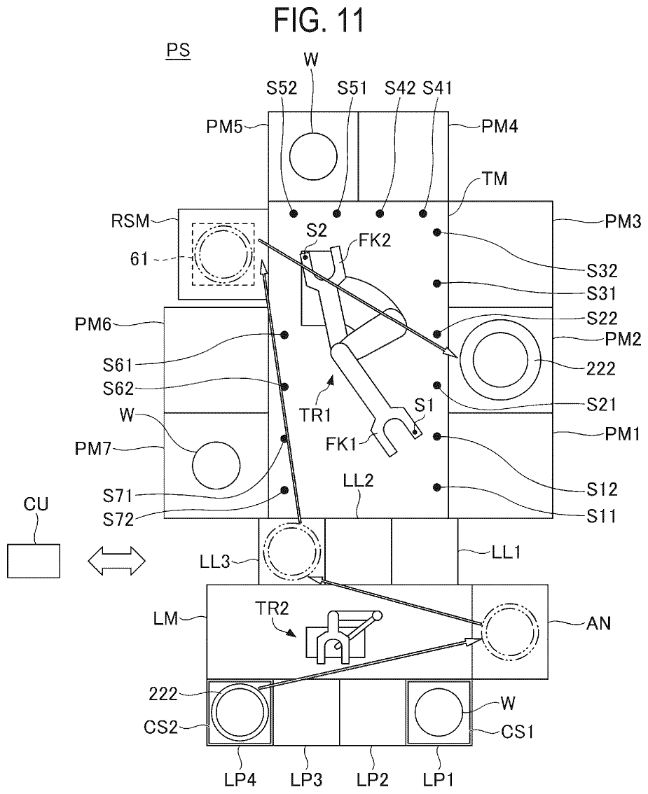

FIG. 10 is a schematic cross-sectional view illustrating a plasma processing apparatus 1A according to another embodiment. FIG. 11 is a schematic plan view illustrating the substrate processing system PS including the plasma processing apparatus 1A. As illustrated in FIGS. 10 and 11, the substrate processing system PS according to another embodiment is different from the above embodiments in that an additional ring 220 is placed on the substrate support 11 of the processing modules PM1 to PM7 (the plasma processing apparatus 1A). Other configurations may be similar to those of the plasma processing apparatus 1 illustrated in FIGS. 2 and 3.

The plasma processing apparatus 1A includes a substrate support 16 provided in the plasma processing space 10s to support the substrate W. The substrate support 16 is supported by a support 17 formed of an insulating material such as quartz. The support 17 extends upward from the bottom of the plasma processing chamber 10. The support 17 has a cylindrical shape.

The substrate support 16 has a first region 161 and a second region 162. The first region 161 supports the substrate W. The first region 161 is a substantially circular region in a plan view. The first region 161 may include a base 18 and an electrostatic chuck 19. The first region 161 may be constituted with a portion of the base 18 and a portion of the electrostatic chuck 19. The base 18 is formed of a conductive material such as aluminum. The base 18 has a substantially disc shape. The base 18 constitutes a lower electrode.

The substrate support 16 includes a main body 2 and a ring assembly (ring) 220. The main body 2 includes the base 18 and the electrostatic chuck 19. The main body 2 has a substrate support region 2a for supporting the substrate W, an annular region 2b for supporting the ring assembly 220, and a sidewall 2c extending in the vertical direction between the substrate support region 2a and the annular region 2b. The annular region 2b surrounds the substrate support region 2a. The annular region 2b is located lower than the substrate support region 2a. Accordingly, an upper end of the sidewall 2c is connected to the substrate support region 2a, and a lower end of the sidewall 2c is connected to the annular region 2b.

A flow path 18f (support temperature adjustment mechanism 116) is formed inside the base 18. The flow path 18 is a flow path through which the heat exchange medium flows. The heat exchange medium may be a liquid refrigerant or a refrigerant (for example, Freon) that cools the base 18 by vaporization of the liquid refrigerant. A supply device for supplying the heat exchange medium (for example, a chiller unit) is connected to the flow path 18f. The supply device is provided outside the plasma processing chamber 10. The heat exchange medium is supplied from the supply device to the flow path 18f. The heat exchange medium supplied to the flow path 18f returns to the supply device.

The electrostatic chuck 19 is provided on the base 18. The substrate W is placed on both the first region 161 and the electrostatic chuck 19 when being processed inside the plasma processing chamber 10.

The second region 162 extends around the first region 161 in a radially outward direction to surround the first region 161. The second region 162 is a substantially annular region in a plan view. The ring assembly 220 is placed on the second region 162. The second region 162 may include the base 18. The second region 162 may include the electrostatic chuck 19. The second region 162 may be constituted with another portion of the base 18 and another portion of the electrostatic chuck 19. The substrate W is placed on the electrostatic chuck 19 in a region surrounded by the ring assembly 220.

The second region 162 of the main body 2 is formed with a plurality of (for example, three) through-holes 162h, which extend vertically between the annular region 2b and a lower surface 2d of the main body 2. The number of through-holes 162h is the same as the number of lift pins 53 of a second lifter 52A, which will be described later.

The electrostatic chuck 19 includes a main body 19m and an electrode 19e provided inside the main body 19m. The main body 19m is formed of a dielectric material such as aluminum oxide or aluminum nitride and has a substantially disc shape. The electrode 19e has a film shape. The electrode 19e is electrically connected to a DC power supply via a switch. When a voltage is applied from the DC power supply to the electrode 19e, an electrostatic attraction force is generated between the electrostatic chuck 19 and the substrate W. Due to the electrostatic attraction force thus generated, the substrate W is attracted to the electrostatic chuck 19 and is held by the electrostatic chuck 19.

The plasma processing apparatus 1A further includes an outer peripheral member 27. The outer peripheral member 27 extends circumferentially along the substrate support 16 (including the support 17, the base 18, the electrostatic chuck 19, and the ring assembly 220) in the radially outward direction. The outer peripheral member 27 may be constituted with one or more components. The outer peripheral member 27 may be formed of an insulating material such as quartz.

The ring assembly 220 includes a lower ring 221 and an upper ring 222. Each of the lower ring 221 and the upper ring 222 has an annular shape. Each of the lower ring 221 and the upper ring 222 is formed of a material that is appropriately selected according to plasma processing performed in the plasma processing apparatus 1A. Each of the lower ring 221 and the upper ring 222 is formed of, for example, silicon or silicon carbide.

The lower ring 221 is placed on the annular region 2b. The lower ring 221 may be placed on both the second region 162 and the electrostatic chuck 19. The lower ring 221 may also be placed on components other than the electrostatic chuck 19 in the second region 162.

A lower surface of the upper ring 222 is substantially flat. The lower surface of the upper ring 222 includes a tapered surface to define a recess. The lower surface of the upper ring 222 defines a plurality of recesses. The number of tapered surfaces and the number of recesses on the upper ring 222 may be the same as the number of lift pins 53 of the second lifter 52A. Each recess is sized such that a tip of a second columnar portion 532 of the corresponding lift pin 53 is fitted into the respective recess. The upper ring 222 is arranged on the lower ring 221 such that each recess is disposed in alignment with a respective lift pin 53 and a respective through-hole 221h.

The upper ring 222 is accommodated in a recess of the lower ring 221. When the lower ring 221 and the upper ring 222 are arranged on the annular region 2b, the upper surface of an outer portion of the lower ring 221 and the upper surface of the upper ring 222 may be substantially at the same height as the upper surface of the substrate W on the substrate support region 2a. The upper ring 222 has an inner peripheral surface 222a, which faces an end surface of the substrate W on the substrate support region 2a when the lower ring 221 and the upper ring 222 are arranged on the annular region 2b.

The second lifter 52A includes the plurality of lift pins 53, and vertically moves the lower ring 221 and the upper ring 222. The number of lift pins 53 may be set to, for example, three, to vertically move the ring assembly 220 while supporting the ring assembly 220.

Each lift pin 53 may be formed of an insulating material. For example, each lift pin 53 may be formed of sapphire, alumina, quartz, silicon nitride, aluminum nitride or resin. Each lift pin 53 includes a first columnar portion 531 and the second columnar portion 532. The first columnar portion 531 extends in the vertical direction. The first columnar portion 531 has a first upper end surface 531t. The first upper end surface 531t may come into contact with the lower surface of the lower ring 221.

The second columnar portion 532 extends vertically upward of the first columnar portion 531. The second columnar portion 532 is narrower than the first columnar portion 531 to expose the first upper end surface 531t. Each of the first columnar portion 531 and the second columnar portion 532 has a cylindrical shape. A diameter of the first columnar portion 531 is greater than that of the second columnar portion 532. The second columnar portion 532 is movable up and down via the through-hole 221h. A vertical length of the second columnar portion 532 is greater than a vertical thickness of a region of the lower ring 221 where the upper ring 222 is placed.

The second columnar portion 532 has a second upper end surface 532t. The second upper end surface 532t may come into contact with the upper ring 222. A tip of the second columnar portion 532 having the second upper end surface 532t may be tapered so as to be fitted into a respective recess in the upper ring 222.

The second columnar portion 532 may include a first portion 532a and a second portion 532b. The first portion 532a is columnar and extends upward from the first columnar portion 531. The second portion 532b is also columnar and extends upward from the first portion 532a. The second portion 532b includes the second upper end surface 532t. A width of the first portion 532a is greater than that of the second portion 532b.

Each of the first columnar portion 531, the first portion 532a, and the second portion 532b may have a cylindrical shape. A diameter of the first columnar portion 531 is greater than that of the first portion 532a, and a diameter of the first portion 532a is greater than that of the second portion 532b.

The second columnar portion 532 may include a third portion 532c. The third portion 532c extends between the first portion 532a and the second portion 532b. The third portion 532c has a tapered surface.

The second lifter 52A includes one or more actuators 522. The one or more actuators 522 are configured to vertically move the plurality of lift pins 53. Each of the one or more actuators 522 may include, for example, a motor.

In the substrate processing system PS illustrated in FIG. 11, a path along which a first ring PFR, which corresponds to the upper ring 222 illustrated in FIG. 10, is replaced. The first ring PFR is stored in, for example, a ring storage container CS2, which is placed on the load port LP4. The first ring PFR stored in the ring storage container CS2 may be a new (unused) one or one which was used but not worn so much (hereinafter sometimes referred to as a “replacement first ring PFR”).

The controller CU transfers the replacement first ring PFR from the atmospheric transfer module LM to perform replacement or other operations. However, before transferring the replacement first ring PFR to a processing module for replacement target among the processing modules PM1 to PM7, the controller CU loads the replacement first ring PFR into the temperature adjuster 61 of the ring storage module RSM. The controller CU adjusts a temperature of the replacement first ring PFR using the temperature adjuster 61, and transfers the replacement first ring PFR, the temperature of which has been adjusted, to the processing module for replacement target.

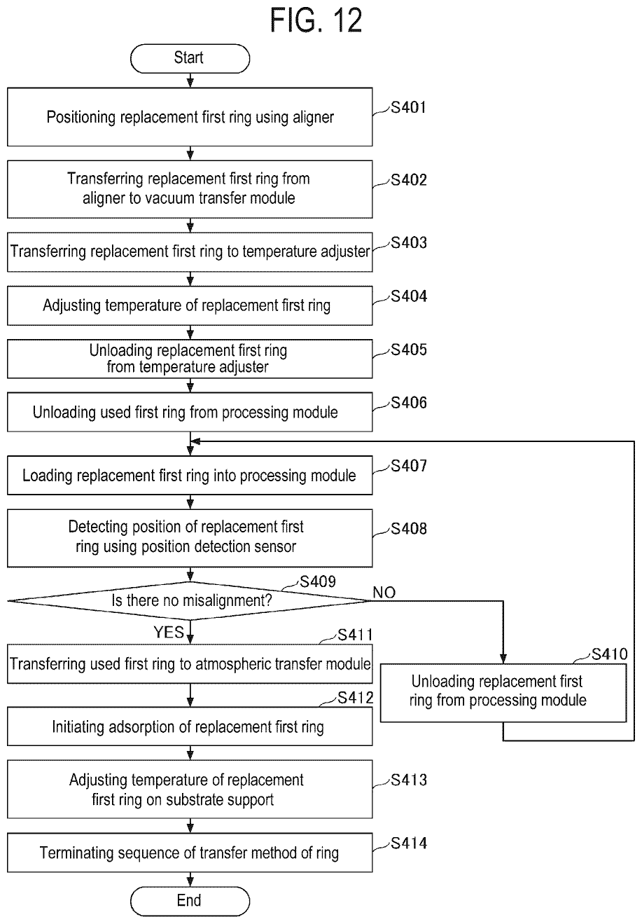

FIG. 12 is a flowchart illustrating a transfer method of a fourth example. In addition, hereinafter, a case of transferring the first ring PFR between the ring storage container CS2 and the processing module PM1 will be described. Even when the processing module for replacement target is one of the other processing modules PM2 to PM7, the same method as that used when the processing module for replacement target is the processing module PM1 may be applied. The transfer method of the fourth example initiates when the controller CU receives an instruction to replace the first ring PFR.

The transfer method of the fourth example includes Operations S401 to S414 as illustrated in FIG. 12. Operations S401 to S414 are performed by the controller CU configured to control the individual constituent elements of the substrate processing system PS.

In Operation S401, the controller CU causes the transfer robot TR2 of the atmospheric transfer module LM to unload the replacement first ring PFR stored in the ring storage container CS2 and load the same into the aligner AN, and causes the aligner AN to perform positioning of the replacement first ring PFR. The positioning may include aligning a rotational position of the replacement first ring PFR with a target position. The positioning may include aligning a central position of the replacement first ring PFR with a target position.

In Operation S402, the controller CU transfers the replacement first ring PFR, which has been subjected to the positioning, from the aligner AN to the vacuum transfer module TM. Specifically, first, the transfer robot TR2 of the atmospheric transfer module LM unloads the replacement first ring PFR, which has been subjected to the positioning, from the aligner AN and loads the same into the load lock module LL3, an internal pressure of which has been increased to atmospheric pressure. Subsequently, the internal pressure of the load lock module LL3 is reduced. Subsequently, the transfer robot TR1 unloads the replacement first ring PFR from the load lock module LL3. In Operation S402, the load lock modules LL1 and LL2 may be used instead of the load lock module LL3.

In Operation S403, the controller CU causes the transfer robot TR1 to load the replacement first ring PFR into the temperature adjuster 61 of the ring storage module RSM.

In Operation S404, the controller CU causes the temperature adjuster 61 to adjust the temperature of the replacement first ring PFR. A target temperature during the temperature adjustment is, for example, the same as the temperature of the substrate support 11 of the processing module PM1 for replacement target (the internal temperature of the plasma processing chamber 10). Thus, the temperature of the replacement first ring PFR is appropriately adjusted before the replacement first ring PFR is transferred to the processing module PM1.

In Operation S405, the controller CU causes the transfer robot TR1 to unload the replacement first ring PFR from the temperature adjuster 61.

In Operation S406, the controller CU causes the transfer robot TR1 to unload a first ring (hereinafter sometimes referred to as a “used first ring PER”), which was used during the substrate processing while being placed on the substrate support 11 of the processing module PM1. At this time, for example, the transfer robot TR1 holds the replacement first ring PFR with the upper fork FK1 and holds the used first ring PFR with the lower fork FK2. However, such a holding manner performed by the transfer robot TR1 may be exchanged.

In Operation S407, the controller CU causes the transfer robot TR1 to load the replacement first ring PFR into the processing module PM1. When the replacement first ring PFR is held by the upper fork FK1 and the used first ring PFR is held by the lower fork FK2, the replacement first ring PFR is located higher than the used first ring PFR. Therefore, even if particles or the like adhering to the used first ring PFR fall, they may be prevented from adhering to the replacement first ring PFR.

In Operation S408, the controller CU causes the position detection sensor S1 provided on the upper fork FK1 to detect a position of the replacement first ring PFR loaded into the processing module PM1.

In Operation S409, the controller CU determines whether or not misalignment occurs in the first replacement ring PFR based on the detected position of the replacement first ring PFR. When the misalignment is determined to occur in the replacement first ring PFR (NO in Operation S409), the controller CU proceeds to Operation S410. When no misalignment is determined to occur in the replacement first ring PFR (YES in Operation S408), the controller CU proceeds to Operation S411.

In Operation S410, the controller CU causes the transfer robot TR1 to unload the replacement first ring PFR from the processing module PM1. After Operation S410, the controller CU returns to Operation S407 where the position of the replacement first ring PFR, which was unloaded from the processing module PM1, is corrected by the transfer robot TR1. Thereafter, the replacement first ring PFR is loaded into the processing module PM1.

In Operation S411, the controller CU transfers the used first ring PFR, which was unloaded from the processing module PM1, from the vacuum transfer module TM to the atmospheric transfer module LM. Specifically, first, the transfer robot TR1 loads the used first ring PFR into the load lock module LL1, an internal pressure of which has been reduced to a vacuum. Subsequently, the internal pressure of the load lock module LL1 is increased to atmospheric pressure. Subsequently, the transfer robot TR2 of the atmospheric transfer module LM unloads the used first ring PFR from the load lock module LL1, and loads the same into the ring storage container CS2. In Operation S411, the load lock modules LL2 and LL3 may be used instead of the load lock module LL1.

In Operation S412, the controller CU initiates the attraction and holding of the replacement first ring PFR by the electrostatic chuck 19.

In Operation S413, the controller CU causes the support temperature adjustment mechanism 116 of the substrate support 16 to adjust the temperature of the replacement first ring PFR. Through the above-described processing flow, the temperature of the replacement first ring PFR has been adjusted in advance by the temperature adjuster 61. Therefore, the controller CU may significantly shorten a time required to execute Operation S413.

In Operation S414, the controller CU terminates a sequence of the transfer method for the replacement first ring PFR. Thereafter, the controller CU may load the substrate W into the processing module PM1 in which the replacement first ring PFR is accommodated, and may perform the substrate processing on the substrate W in a satisfactory manner.

According to the transfer method of the fourth example as described above, the temperature of the replacement first ring FR is adjusted by the temperature adjuster 61 before the replacement first ring PFR is loaded into the processing module PM1. Thus, according to the substrate processing system PS, it is possible to shorten a time required to adjust the temperature of the replacement first ring PFR in the processing module PM1. As a result, the substrate processing system PS may quickly initiate the substrate processing in the processing module PM1, thereby improving the productivity of the substrate processing. In addition, in the above embodiments, the case of replacing the first ring PFR has been described as an example, but the second ring (the lower ring 221) arranged outside the first ring PFR may be replaced by the same method.

In addition, even in the transfer method of the fourth example, the orders of some of Operations S401 to S414 illustrated in FIG. 12 may be changed, some of Operations may be omitted, or other Operations may be added.

For example, Operations S406 and S411 may be performed in parallel with the execution of Operation S404. Alternatively, Operations S406 and S411 may be performed in parallel with the execution of Operations S401 and S402, respectively. Further, for example, in a case in which the first ring PFR is not attracted and held by the electrostatic chuck 19, Operation S412 may be omitted.

The substrate processing system PS and the transfer method which transfer the first ring PFR may be embodied in various modifications. As an example, in the substrate processing system PS, the temperature adjuster 61 for adjusting the temperature of the replacement first ring PFR may be provided on the side of the atmospheric transfer module LM. For example, the temperature adjuster 61 may be provided in the ring storage container CS2, or may be provided in the aligner AN. In this case, in the transfer method, the temperature of the replacement first ring PFR is adjusted before transferring the replacement first ring PFR into the vacuum transfer module TM. This makes it possible to further shorten a time required to adjust the temperature of the replacement first ring PFR by the temperature adjuster 61 on the side of the vacuum transfer module TM. Alternatively, in the case in which the temperature of the replacement first ring PFR is adjusted by the temperature adjuster 61 on the side of the atmospheric transfer module LM, the substrate processing system PS may directly transfer the replacement first ring PFR to a processing module for replacement target via the load lock modules LL1 to LL3.

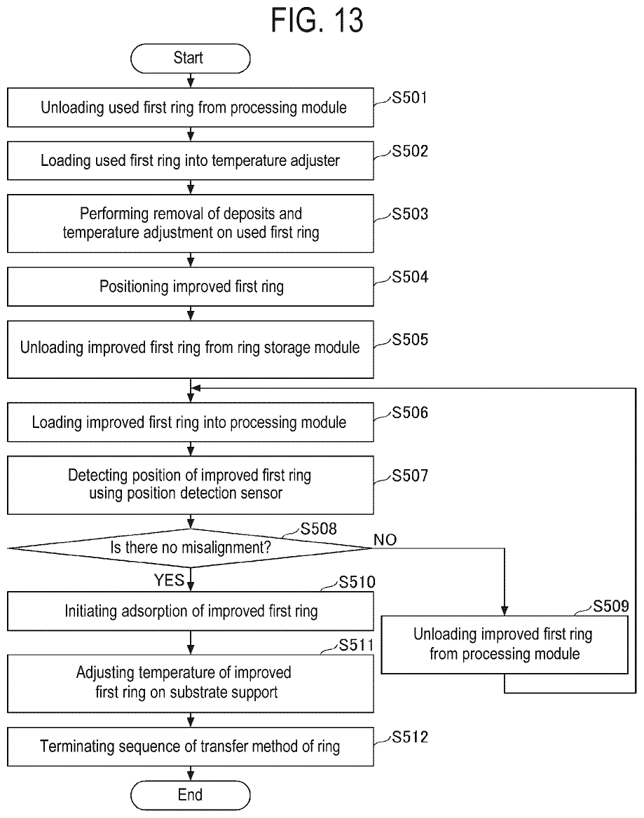

FIG. 13 is a flowchart illustrating a transfer method of a fifth example. The transfer method of the fifth example is a method including removing, by the temperature adjuster 61, deposits adhering to the first ring PFR which was used in the processing modules PM1 to PM7 of the substrate processing system PS, and returning the first ring PER, from which the deposits have been removed (hereinafter sometimes referred to as an “improved first ring PFR”), to the processing modules PM1 to PM7. The controller CU initiates the transfer method of the fifth example based on triggers such as user's instructions, the number of substrate processing, a quality of the substrate W, sensor values obtained in the respective processing modules PM1 to PM7, and the occurrence of errors. In addition, even in the transfer method of the fifth example, a case of transferring the first ring PFR between the ring storage module RSM and the processing module PM1 will be described. Even if the processing module is one of the other processing modules PM2 to PM7, the same method as that used when the processing module is the processing module PM1 may be applied.

The transfer method of the fifth example includes Operations S501 to S512 as illustrated in FIG. 13. Operations S501 to S512 are performed by the controller CU configured to control the individual constituent elements of the substrate processing system PS.

In Operation S501, the controller CU causes the transfer robot TR1 to unload the used first ring PFR (the first ring PFR to which the deposits adhere), which was used during the substrate processing while being placed on the substrate support 11 of the processing module PM1, from the processing module PM1.

In Operation S502, the controller CU causes the transfer robot TR1 to load the used first ring PFR, which was unloaded from the processing module PM1, into the temperature adjuster 61 of the ring storage module RSM (for example, the first temperature adjustment device 62).

In Operation S503, the controller CU causes the temperature adjuster 61 to remove deposits adhering to the used first ring PFR loaded thereinto and adjust the temperature of the used first ring PFR. Thus, the deposits adhering to the used first ring PFR may be removed in a satisfactory manner, which makes it possible to obtain the improved first ring PFR.

After the removal of the deposits, the temperature adjuster 61 proceeds to an operation of adjusting the temperature of the improved first ring PFR as a pre-processing operation before returning the improved first ring PFR to the processing module PM1. Thus, the temperature of the improved first ring PFR is adjusted to be approximately coincided with the temperature of the substrate support 11 of the processing module PM1.

In Operation S504, the controller CU causes the transfer robot TR1 to take out the improved first ring PFR, the temperature of which has been adjusted, from the temperature adjuster 61 and place the same on the stage 73 of the same ring storage module RSM. Subsequently, the controller CU executes the alignment (positioning) on the improved first ring PFR.

Operations S505 to S512 may be similar to Operations S110 to S117 illustrated in FIG. 6.

As described above, according to the transfer method of the fifth example, the temperature adjuster 61 removes the deposits adhering to the first ring PFR and adjusts the temperature of the first ring PFR, which makes it possible to improve the productivity of the substrate processing. Thus, in the substrate processing system PS, the operation of removing the deposits adhering to the first ring PFR in the processing modules PM1 to PM7 may be omitted. This makes it possible to suppress contamination (such as scattering of particles) from occurring in the processing modules PM1 to PM7 due to the removal of the deposits, which results in an increase in quality of the substrate processing.

In addition, similar to the transfer method of the first example, even in the transfer method of the fifth example, the orders of some of Operations S501 to S512 illustrated in FIG. 13 may be changed, some of Operations may be omitted, or other Operations may be added. For example, Operation S504 may be performed between Operation S501 and Operation S502. Further, for example, Operation S510 may be omitted in a case in which the first ring PFR is not attracted and held by the electrostatic chuck 112.

The above-described embodiments may include the following aspects.

### (Supplementary Note 1)

A substrate processing system includes:
a processing module including a processing chamber and a substrate support provided inside the processing chamber, the substrate support having a substrate support surface and a ring support surface that surrounds the substrate support surface to support at least one ring;
a vacuum transfer module connected to the processing module and including a transfer robot configured to transfer the at least one ring;
a temperature adjuster configured to be capable of adjusting a temperature of the at least one ring;
a controller configured to sequentially execute:
adjusting the temperature of the at least one ring by the temperature adjuster before loading the at least one ring into the processing module; and
transferring, by the transfer robot, the at least one ring, the temperature of which has been adjusted by the temperature adjuster, so as to place the at least one ring on the substrate support.

### (Supplementary Note 2)

In the substrate processing system of Supplementary Note 1 or 2 above, the at least one ring is a replacement ring, and
the controller is further configured to execute unloading the at least one ring, which was used while being supported on the substrate support, before loading the replacement ring into the processing module.

### (Supplementary Note 3)

In the substrate processing system of Supplementary Note 2 above, the controller unloads the at least one ring which was used in the processing module, while adjusting the temperature of the at least one ring for replacement using the temperature adjuster.

### (Supplementary Note 4)

In the substrate processing system of any one of Supplementary Notes 1 to 3 above, the at least one ring includes a first ring provided on the ring support surface and a second ring provided to surround the first ring and configured to overlap the first ring from below in a plan view, and
the adjusting the temperature of the at least one ring includes adjusting the temperature of the first ring for replacement, and transferring, by the transfer robot, the first ring for replacement, the temperature of which has been adjusted, so as to place the first ring on the substrate support.

### (Supplementary Note 5)

In the substrate processing system of any one of Supplementary Notes 1 to 4 above, the at least one ring includes a first ring provided on the ring support surface and a second ring provided to surround the first ring and configured to overlap the first ring from below in a plan view, and
the adjusting the temperature of the at least one ring includes adjusting temperatures of the first ring for replacement and the first ring for replacement, and transferring, by the transfer robot, the first ring for replacement and the second ring for replacement, the temperatures of which have been adjusted, so that the first ring for replacement and the first ring for replacement are placed on the substrate support.

### (Supplementary Note 6)

In the substrate processing system of Supplementary Note 4 above, the controller is further configured to execute unloading the first ring, which was used while being supported on the substrate support, before loading the first ring for replacement into the processing module.

### (Supplementary Note 7)

In the substrate processing system of Supplementary Note 6 above, the controller unloads the first ring which was used in the processing module, while adjusting the temperature of the first ring for replacement using the temperature adjuster.

### (Supplementary Note 8)

In the substrate processing system of Supplementary Note 5 above, the controller is further configured to execute unloading the first ring and the second ring, which have been used while being supported on the substrate support, before loading the first ring for replacement and the second ring for replacement into the processing module.

### (Supplementary Note 9)

In the substrate processing system of Supplementary Note 8 above, the unloading the first ring and the second ring, which have been used while being supported on the substrate support includes unloading the first ring and subsequently unloading the second ring, and
the loading the first ring and the second rings includes loading the first ring for replacement and subsequently loading the second ring for replacement.

### (Supplementary Note 10)

In the substrate processing system of Supplementary Note 5 above, the controller unloads the first ring and the second ring, which have been used in the processing module, while adjusting the temperatures of the first ring for replacement and the second ring for replacement by the temperature adjuster.

### (Supplementary Note 11)

In the substrate processing system of Supplementary Note 5 above, the temperature adjuster is capable of simultaneously adjusting the temperatures of the first ring and the second ring.

### (Supplementary Note 12)

In the substrate processing system of Supplementary Note 11 above, the temperature adjuster includes a first temperature adjustment device configured to be capable of adjusting the temperature of the first ring, and a second temperature adjustment device configured to be capable of adjusting the temperature of the second ring.

### (Supplementary Note 13)

The substrate processing system of any one of Supplementary Notes 1 to 12 above further includes a ring storage module connected to the vacuum transfer module and configured to be capable of storing the at least one ring,
wherein the temperature adjuster is provided in the ring storage module.

### (Supplementary Note 14)

In the substrate processing system of Supplementary Note 13 above, the ring storage module includes the temperature adjuster, a basket configured to store the at least one ring, and a positioning device configured to position the at least one ring.

### (Supplementary Note 15)

In the substrate processing system of Supplementary Note 14 above, the controller is configured to sequentially execute: taking out the at least one ring stored in the basket to load the same into the temperature adjuster using the transfer robot; adjusting the temperature of the at least one ring using the temperature adjuster; and loading the at least one ring, the temperatures of which have been adjusted, into the positioning device where the at least one ring is positioned.

### (Supplementary Note 16)

In the substrate processing system of any one of Supplementary Notes 1 to 15 above, the temperature adjuster adjusts the temperature of the at least one ring within a range of 10 degrees C. from a temperature of the substrate support of the processing module into which the at least one ring is to be loaded.

### (Supplementary Note 17)

In the substrate processing system of any one of Supplementary Notes 1 to 16 above, the temperature adjuster adjusts the temperature of the at least one ring within a range of 10 degrees C. from a temperature of a heat exchange medium circulating through a flow path of the substrate support of the processing module into which the at least one ring is to be loaded.

### (Supplementary Note 18)

In the substrate processing system of any one of Supplementary Notes 1 to 17 above, the temperature adjuster includes a temperature adjustment room in which one ring of the at least one ring is accommodated, and a housing configured to close the internal temperature adjustment room to adjust a temperature of the one ring.

### (Supplementary Note 19)

The substrate processing system of any one of Supplementary Notes 1 to 18 above, wherein the transfer robot includes a position detection sensor configured to detect a position of the at least one ring placed on the substrate support,
the controller determines whether or not a misalignment occurs in the at least one ring detected by the position detection sensor, and
when the misalignment is determined to occur in the at least one ring, the controller adjusts the position of the at least one ring.

### (Supplementary Note 20)

In the substrate processing system of any one of Supplementary Notes 1 to 19 above, the controller is configured to sequentially execute: loading the at least one ring, which was used and unloaded, into the temperature adjuster; removing deposits adhering to the at least one ring while adjusting the temperature of the at least one ring using the temperature adjuster; and loading the at least one ring, from which the deposits have been removed, into the processing module.

### (Supplementary Note 21)

In the substrate processing system of any one of Supplementary Notes 1 to 19 above, the controller is configured to sequentially execute: loading the at least one ring, which was used and unloaded, into the temperature adjuster; removing deposits adhering to the at least one ring and then adjusting the temperature of the at least one ring using the temperature adjuster; and loading the at least one ring, from which the deposits have been removed, into the processing module.

### (Supplementary Note 22)

The substrate processing system of any one of Supplementary Notes 1 to 21 above further includes:
a load lock module connected to the vacuum transfer module;
an atmospheric transfer module connected to the vacuum transfer module via the load lock module;
a load port connected to the atmospheric transfer module; and
a ring storage container placed on the load port,
wherein the at least one ring is a replacement ring, and
wherein the controller is configured to sequentially execute: when transferring the replacement ring stored in the ring storage container from the atmospheric transfer module to the processing module,
loading the replacement ring into the temperature adjuster;
adjusting a temperature of the replacement ring using the temperature adjuster; and
transferring the replacement ring, the temperature of which has been adjusted by the temperature adjuster, and loading the replacement ring into the processing module.

### (Supplementary Note 23)

In the substrate processing system of Supplementary Note 22 above, the at least one ring includes a first ring provided to surround the substrate support surface, and a second ring provided to surround the first ring and configured to overlap the first ring from below in a plan view, and
the adjusting the temperature of the at least one ring includes adjusting a temperature of the first ring for replacement, and transferring, by the transfer robot, the first ring for replacement, the temperature of which has been adjusted, so as to place the first ring on the substrate support.

### (Supplementary Note 24)

In the substrate processing system of Supplementary Note 23 above, the controller is further configured to execute unloading the first ring, which was used while being supported on the substrate support, before loading the first ring for replacement.

### (Supplementary Note 25)

In the substrate processing system of Supplementary Note 24 above, the controller unloads the first ring which was used in the processing module, while adjusting the temperature of the first ring for replacement using the temperature adjuster.

### (Supplementary Note 26)

A substrate processing system includes:
a processing module including a processing chamber and a substrate support provided inside the processing chamber, the substrate support having a substrate support surface and a ring support surface that surrounds the substrate support surface to support at least one ring;
a vacuum transfer module connected to the processing module and including a transfer robot configured to transfer the at least one ring;
a temperature adjuster configured to be capable of adjusting a temperature of the at least one ring; and
a controller configured to sequentially execute:
   adjusting the temperature of the at least one ring using the temperature adjuster before placing the at least one ring on the substrate support surface; and
   transferring, using the transfer robot, the at least one ring, the temperature of which has been adjusted by the temperature adjuster, so as to place the at least one ring on the substrate support.

### (Supplementary Note 27)

A transfer method of transferred at least one ring to a processing module which includes a processing chamber, and a substrate support provided inside the processing chamber and having a substrate support surface and a ring support surface for surrounding the substrate support surface to support a ring, the transfer method comprising a sequence of:
loading, by a transfer robot of a vacuum transfer module connected to the processing module, the ring to a temperature adjuster connected to the vacuum transfer module;
adjusting, by the temperature adjuster, a temperature of the ring; and
transferring, by the transfer robot, the ring, the temperature of which has been adjusted by the temperature adjuster, so as to place the ring on the substrate support.

In addition, the present disclosure is not limited to the configurations illustrated herein, such as combinations with other elements in the configurations exemplified in the above-described embodiments or the like. These points may be changed without departing from the gist of the present disclosure, and may be appropriately determined according to an application form thereof. Further, the matters described in the aforementioned embodiments may have other configurations to the extent that they are not contradictory, and may be combined with each other to the extent that they are not contradictory.

For example, in the above embodiments, a capacitively-coupled plasma apparatus has been described as an example, but the present disclosure is not limited thereto and may be applied to other types of plasma apparatuses. For example, an inductively-coupled plasma (ICP) apparatus may be used instead of the capacitively-coupled plasma apparatus. In this case, the inductively-coupled plasma apparatus includes an antenna and a lower electrode. The lower electrode is disposed inside the substrate support, and the antenna is disposed in an upper portion of the chamber or above the chamber. Further, the RF generator is coupled to the antenna, and the DC generator is coupled to the lower electrode. Therefore, the RF generator is coupled to the upper electrode of the capacitively coupled plasma apparatus, or to the antenna of the inductively coupled plasma apparatus. That is, the RF generator is coupled to the plasma processing chamber 10.

According to one aspect, it is possible to enhance the productivity of substrate processing.

While certain embodiments have been described, these embodiments have been presented by way of example only, and are not intended to limit the scope of the disclosures. Indeed, the embodiments described herein may be embodied in a variety of other forms. Further, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing system comprising:
a processing module including a processing chamber and a substrate support provided inside the processing chamber, the substrate support having a substrate support surface and a ring support surface that surrounds the substrate support surface to support at least one ring;
a vacuum transfer module connected to the processing module and including a transfer robot configured to transfer the at least one ring;
a ring storage module connected to the vacuum transfer module and configured to be capable of storing the at least one ring;
a temperature adjuster provided in the ring storage module and configured to be capable of adjusting a temperature of the at least one ring;
a controller configured to sequentially execute:
adjusting the temperature of the at least one ring by the temperature adjuster before loading the at least one ring into the processing module; and
transferring, by the transfer robot, the at least one ring, the temperature of which has been adjusted by the temperature adjuster, so as to place the at least one ring on the substrate support.

2. The substrate processing system of claim 1, wherein the at least one ring is a replacement ring, and
wherein the controller is further configured to execute unloading the at least one ring, which was used while being supported on the substrate support, before loading the replacement ring into the processing module.

3. The substrate processing system of claim 1, wherein the at least one ring includes a first ring provided on the ring support surface and a second ring provided to surround the first ring and configured to overlap the first ring from below in a plan view, and
wherein the adjusting the temperature of the at least one ring includes adjusting a temperature of the first ring for replacement, and transferring, by the transfer robot, the first ring for replacement, the temperature of which has been adjusted, so as to place the first ring on the substrate support.

4. The substrate processing system of claim 1, wherein the at least one ring includes a first ring provided on the ring support surface and a second ring provided to surround the first ring and configured to overlap the first ring from below in a plan view, and
wherein the adjusting the temperature of the at least one ring includes adjusting temperatures of the first ring for replacement and the second ring for replacement, and transferring, by the transfer robot, the first ring for replacement and the second ring for replacement so that the first ring for replacement and the second ring for replacement are placed on the substrate support.

5. The substrate processing system of claim 4, wherein the temperature adjuster includes a first temperature adjustment device configured to be capable of adjusting the temperature of the first ring, and a second temperature adjustment device configured to be capable of adjusting the temperature of the second ring.

6. The substrate processing system of claim 1, wherein the temperature adjuster adjusts the temperature of the at least one ring within a range of 10 degrees C. from a temperature of the substrate support of the processing module into which the at least one ring is to be loaded.

7. The substrate processing system of claim 1, wherein the temperature adjuster adjusts the temperature of the at least one ring within a range of 10 degrees C. from a temperature of a heat exchange medium circulating through a flow path of the substrate support of the processing module into which the at least one ring is to be loaded.

8. The substrate processing system of claim 1, wherein the temperature adjuster includes a temperature adjustment room in which one ring of the at least one ring is accommodated, and a housing configured to close the internal temperature adjustment room to adjust a temperature of the one ring.

9. The substrate processing system of claim 1, further comprising:
a load lock module connected to the vacuum transfer module;
an atmospheric transfer module connected to the vacuum transfer module via the load lock module;
a load port connected to the atmospheric transfer module; and
a ring storage container placed on the load port,
wherein the at least one ring is a replacement ring, and
wherein the controller is configured to sequentially execute: when transferring the replacement ring stored in the ring storage container from the atmospheric transfer module to the processing module,
loading the replacement ring into the temperature adjuster;
adjusting a temperature of the replacement ring using the temperature adjuster; and
transferring the replacement ring, the temperature of which has been adjusted by the temperature adjuster, and loading the replacement ring into the processing module.

10. The substrate processing system of claim 9, wherein the at least one ring includes a first ring provided to surround the substrate support surface, and a second ring provided to surround the first ring and configured to overlap the first ring from below in a plan view, and
wherein the adjusting the temperature of the at least one ring includes adjusting a temperature of the first ring for replacement, and transferring, by the transfer robot, the first ring for replacement, the temperature of which has been adjusted, so as to place the first ring on the substrate support.

11. A substrate processing system comprising:
a processing module including a processing chamber and a substrate support provided inside the processing chamber, the substrate support having a substrate support surface and a ring support surface that surrounds the substrate support surface to support at least one ring;
a vacuum transfer module connected to the processing module and including a transfer robot configured to transfer the at least one ring;
a temperature adjuster connected to the vacuum transfer module and configured to be capable of adjusting a temperature of the at least one ring; and
a controller configured to sequentially execute:
adjusting the temperature of the at least one ring using the temperature adjuster before loading the at least one ring into the processing module; and
transferring, using the transfer robot, the at least one ring, the temperature of which has been adjusted by the temperature adjuster, so as to place the at least one ring on the substrate support.

12. The substrate processing system of claim 11, wherein the at least one ring is a replacement ring, and
wherein the controller is further configured to execute unloading the at least one ring, which was used while being supported on the substrate support, before loading the replacement ring into the processing module.

13. The substrate processing system of claim 11, wherein the at least one ring includes a first ring provided on the ring support surface, and a second ring provided to surround the first ring and configured to overlap the first ring from below in a plan view, and
wherein the adjusting the temperature of the at least one ring includes adjusting a temperature of the first ring for replacement, and transferring, by the transfer robot, the first ring for replacement, the temperature of which has been adjusted, so as to place the first ring on the substrate support.

14. The substrate processing system of claim 11, wherein the at least one ring includes a first ring provided on the ring support surface, and a second ring provided to surround the first ring and configured to overlap the first ring from below in a plan view, and
wherein the adjusting the temperature of the at least one ring includes adjusting temperatures of the first ring for replacement and the second ring for replacement, and transferring, by the transfer robot, the first ring for replacement and the second ring for replacement so that the first ring for replacement and the second ring for replacement are placed on the substrate support.

15. The substrate processing system of claim 14, wherein the temperature adjuster includes a first temperature adjustment device configured to be capable of adjusting the temperature of the first ring, and a second temperature adjustment device configured to be capable of adjusting the temperature of the second ring.

16. The substrate processing system of claim 11, wherein the temperature adjuster adjusts the temperature of the at least one ring within a range of 10 degrees C. from a temperature of the substrate support of the processing module into which the at least one ring is to be loaded.

17. The substrate processing system of claim 11, wherein the temperature adjuster adjusts the temperature of the at least one ring within a range of 10 degrees C. from a temperature of a heat exchange medium circulating through a flow path of the substrate support of the processing module into which the at least one ring is to be loaded.

18. The substrate processing system of claim 11, wherein the temperature adjuster includes a temperature adjustment room in which one ring of the at least one ring is accommodated, and a housing configured to close the internal temperature adjustment room to adjust a temperature of the one ring is adjusted.

19. The substrate processing system of claim 11, further comprising:
a load lock module connected to the vacuum transfer module;
an atmospheric transfer module connected to the vacuum transfer module via the load lock module;
a load port connected to the atmospheric transfer module; and
a ring storage container placed on the load port,
wherein the at least one ring is a replacement ring, and
wherein the controller is configured to sequentially execute: when transferring the replacement ring stored in the ring storage container from the atmospheric transfer module to the processing module,
loading the replacement ring into the temperature adjuster;
adjusting a temperature of the replacement ring using the temperature adjuster, and
transferring the replacement ring, the temperature of which has been adjusted by the temperature adjuster, so that the replacement ring is loaded into the processing module.

20. The substrate processing system of claim 19, wherein the at least one ring includes a first ring provided to surround the substrate support surface, and a second ring provided to surround the first ring and configured to overlap the first ring from below in a plan view, and
wherein the adjusting the temperature of the at least one ring includes adjusting a temperature of the first ring for replacement, and transferring, by the transfer robot, the first ring for replacement, the temperature of which has been adjusted, so as to place the first ring on the substrate support.
